(19) United States
(12) Patent Application Publication
(10) Pub. No.: US 2023/0203234 A1
(43) Pub. Date: Jun. 29, 2023

(54) HOLLOW MICROBALLOONS

(71) Applicant: TOKUYAMA CORPORATION, Shunan-shi, Yamaguchi (JP)

(72) Inventors: Yasutomo SHIMIZU, Tsukuba-shi (JP); Takayoshi KAWASAKI, Tsukuba-shi (JP)

(73) Assignee: TOKUYAMA CORPORATION, Shunan-shi, Yamaguchi (JP)

(21) Appl. No.: 17/914,998

(22) PCT Filed: Mar. 31, 2021
(86) PCT No.: PCT/JP2021/013798

§ 371 Date: Sep. 27, 2022

(30) Foreign Application Priority Data
Mar. 31, 2020 (JP) 2020-061827

(51) Int. Cl. C08G 18/64; C08J 9/32; C08G 83/00; C08G 18/10; C08G 18/08; B24D 3/32

(52) U.S. Cl. CPC C08G 18/64; C08J 9/32; C08G 83/007; C08G 18/10; C08G 18/14; B24D 3/32; C08G 2101/00

(57) ABSTRACT

The hollow microballoons of the invention are hollow microballoons formed of a resin produced by polymerizing a polymerizing composition that contains a polyrotaxane monomer having at least two polymerizable functional groups in the molecule and a polymerizable monomer other than the polyrotaxane monomer having at least two polymerizable functional groups in the molecule. Using the hollow microballoons of the invention, a CMP polishing pad having excellent polishing characteristics and durability can be provided.

### TECHNICAL FIELD

The present invention relates to hollow microballoons.

### BACKGROUND ART

Heretofore, microballoons have been used in various fields including agriculture, medicines, fragrances, liquid crystals, adhesives, electronic material parts and building materials, as microballoons encapsulating a skincare component, a fragrance component, a dye component, an analgesic component, a deodorant component, an antioxidant component, a bactericidal component, a heat storage component or the like, or as hollow microballoons that are hollow inside of the microballoons.

Recently, in particular, hollow microballoons have been investigated for the purpose of forming fine pores in polyurethane(urea)-made polishing pads for chemical mechanical polishing (CMP) of wafer polishing.

Heretofore, as hollow microballoons for CMP polishing pads, there have been known vinylidene chloride resin microballoons formed by dusting the surfaces of hollow microballoons with inorganic particles for the purpose of improving dispersibility in polyurethane(urea), in which, however, there is a possibility that the inorganic particles may cause wafer defects.

Therefore, the present inventors have proposed a polishing pad for CMP having excellent polishing characteristics, by using hollow microballoons formed of a polyurethane(urea) resin membrane having high elasticity and having good compatibility with a polyurethane(urea) resin, in a CMP polishing pad (see PTL 1).

However, with recent micronization of semiconductor interconnections, polishing pads for CMP with higher performance have been demanded, and further improvements in durability and resin physical properties of hollow microballoons have been demanded.

On the other hand, also for other uses than use for CMP polishing pads, improvements in resin physical properties, such as durability of microballoons have been demanded, and PTL 2 discloses, regarding polyurethane(urea) microballoons that encapsulate a heat storage material, a technique of incorporating a polyrotaxane in polyurethane(urea) to improve durability to thereby prevent leakage of the heat storage material.

### CITATION LIST

### Patent Literature

PTL 1: WO2019/198675A1
PTL 2: WO2013/176050A1

### SUMMARY OF INVENTION

### Technical Problem

However, as a result of investigation by the present inventors, it has been known that the method described in PTL 2 can be effective for microballoons that encapsulate a heat storage material, but cannot attain satisfactory durability when applied to hollow microballoons.

Accordingly an object of the present invention is to provide hollow microballoons capable of providing not only polishing characteristics but also excellent durability.

### Solution to Problem

The present inventors have assiduously studied for the purpose of solving the above-mentioned problems and, as a result, have found that, by using hollow microballoons comprising a resin produced by polymerizing a polymerizable composition that contains a polyrotaxane monomer having at least two polymerizable functional groups in the molecule and a polymerizable monomer other than the polyrotaxane monomer having at least two polymerizable functional groups in the molecule, the above-mentioned problems can be solved, and have completed the present invention.

Specifically the present invention provides hollow microballoons comprising a resin produced by polymerizing a polymerizable composition that contains a polyrotaxane monomer having at least two polymerizable functional groups in the molecule and a polymerizable monomer other than the polyrotaxane monomer having at least two polymerizable functional groups in the molecule.

Also the present invention provides a polishing pad for CMP that contains the hollow microballoons.

The present invention including these is as described below.

[1] Hollow microballoons comprising a resin produced by polymerizing a polymerizable composition that contains (A) a polyrotaxane monomer having at least two polymerizable functional groups in a molecule and (B) a polymerizable monomer other than the (A) polyrotaxane monomer having at least two polymerizable functional groups in the molecule.
[2] The hollow microballoons according to the above [1], wherein a content of the (A) polyrotaxane monomer having at least two polymerizable functional groups in the molecule in the polymerizable composition is 1 to 50 parts by mass relative to 100 parts by mass of the total of the content of the (A) polyrotaxane monomer having at least two polymerizable functional groups in the molecule and a content of the (B) polymerizable monomer other than the (A) polyrotaxane monomer having at least two polymerizable functional groups in the molecule.
[3] The hollow microballoons according to the above [1] or [2], wherein the resin comprises at least one selected from the group consisting of a urethane(urea) resin, a melamine resin, a urea resin and an amide resin.
[4] The hollow microballoons according to any one of the above [1] to [3], wherein a polymerizable functional group of the (A) polyrotaxane monomer having at least two polymerizable functional groups in the molecule is a hydroxy group or an amino group.
[5] The hollow microballoons according to any one of the above [1] to [4], wherein a cyclic molecule of the (A) polyrotaxane monomer having at least two polymerizable functional groups in the molecule has a side chain.
[6] The hollow microballoons according to the above [5], wherein a number-average molecular weight of the side chain of the (A) polyrotaxane monomer having at least two polymerizable functional groups in the molecule is 5,000 or less.
[7] The hollow microballoons according to the above [5] or [6], wherein the side chain of the (A) polyrotaxane monomer having at least two polymerizable functional groups in the molecule has the at least two polymerizable functional groups.
[8] A polishing pad for CMP containing the hollow microballoons of any one of the above [1] to [7].

### Advantageous Effects of Invention

The hollow microballoons of the present invention comprises a resin produced by polymerizing a polymerizable composition that contains a polyrotaxane monomer having at least two polymerizable functional groups in the molecule. With that, the hollow microballoons can be given excellent durability.

A polishing pad for CMP that contains such hollow microballoons can express excellent polishing characteristics. For example, it is possible to realize a high polishing rate and to reduce wafer defects.

Though not clear, the mechanism is presumed to be as follows.

It is generally known that, since the cyclic molecule of polyrotaxane moves on the axle molecule, polyrotaxane can be given a stress dispersion performance capable of relaxing a stress concentration site and an excellent elastic recovery performance to deformation.

In the present invention, polyrotaxane is not merely incorporated into the resin that constitutes hollow microballoons but polyrotaxane is made to be one constituent component of the resin to constitute hollow microballoons to thereby provide hollow microballoons having excellent durability in which the entire resin is given the above-mentioned stress dispersion performance and elastic recovery performance. By applying such hollow microballoons to a polishing pad for CMP, it becomes possible to express not only a role of forming fine pores on the polishing surface of a polishing pad for CMP owing to the above-mentioned stress dispersion performance and elastic recovery performance but also to provide a polishing pad for CMP having durability and capable of expressing excellent polishing characteristics and also excellent wear resistance. Further, owing to the characteristics, it becomes possible to reduce wafer defects to occur owing to the polishing sludge of hollow microballoons to be discharged in polishing.

Further, in addition to the use for CMP polishing pads, the hollow microballoons of the present invention are also usable in other various fields of thermal recording materials, agricultural chemicals, medicines, fragrances, liquid crystals, adhesives, electronic material parts, building materials, etc.

### DESCRIPTION OF EMBODIMENTS

The hollow microballoons of the present invention are hollow microballoons comprising a resin produced by polymerizing a polymerizable composition that contains (A) a polyrotaxane monomer having at least two polymerizable functional groups in the molecule (hereinafter this may be referred to also as “polyrotaxane monomer (A)”, or “component (A)”) and (B) a polymerizable monomer other than the (A) polyrotaxane monomer having at least two polymerizable functional groups in the molecule (hereinafter this may be referred to also as “polymerizable monomer (B)”, or “component (B)”). The resin forms the shell region of the hollow microballoon. First, the polyrotaxane monomer (A) is described.

### <(A) Polyrotaxane Monomer>

Polyrotaxane is a known compound and has a composite molecular structure formed of a chainlike axial molecule and a cyclic molecule. Namely, the structure is such that a cyclic molecule encapsulates a chainlike axial molecule and the axial molecule passes through the inside of the ring that the cyclic molecule has. Therefore, the cyclic molecule can freely slide on the axial molecule and, in general, a bulky terminal group is formed at both ends of the axial molecule so as to prevent the cyclic molecule from dropping out of the axial molecule.

In general, in the above-mentioned structure, a case having plural cyclic molecules is referred to as “polyrotaxane”, but in the present invention, “polyrotaxane” includes not only such a case but also a case having one cyclic molecule.

As mentioned above, in a polyrotaxane, a cyclic molecule can slide on a axial molecule. Therefore, it is considered that a polyrotaxane can express a performance called sliding elasticity and can express excellent characteristics. In the present invention, a polyrotaxane is used as one constituent component of the resin that constitute hollow microballoons, and therefore the hollow microballoons can be given characteristics such as excellent durability.

The polyrotaxane monomer (A) for use in the present invention can be synthesized according to a known method, for example, according to the method described in WO2015/068798A1. The constitution of the component (A) is described in detail.

The axial molecule of the polyrotaxane monomer (A) for use in the present invention is not specifically limited so far as it can pass through the ring that a cyclic molecule has, for which, in general, a linear or branched polymer is used.

The polymer for use for the axial molecule includes polyvinyl alcohol, polyvinyl pyrrolidone, cellulosic resin (e.g., carboxymethyl cellulose, hydroxyethyl cellulose, hydroxypropyl cellulose), polyacrylamide, polyethylene oxide, polyethylene glycol, polypropylene glycol, polyvinyl acetal, polyvinyl methyl ether, polyamine, polyethyleneimine, casein, gelatin, starch, olefinic resin (e.g., polyethylene, polypropylene), polyester, polyvinyl chloride, styrenic resin (e.g., polystyrene, acrylonitrile-styrene copolymer resin), acrylic resin (e.g., poly(meth)acrylic acid, polymethyl methacrylate, polymethyl acrylate, acrylonitrile-methyl acrylate copolymer resin), polycarbonate, polyurethane, vinyl chloride-vinyl acetate copolymer resin, polyvinyl butyral, polyisobutylene, polytetrahydrofuran, polyaniline, acrylonitrile-butadiene-styrene copolymer resin (ABS resin), polyamide (e.g., nylon), polyimide, polydiene (e.g., polyisoprene, polybutadiene), polysiloxane (e.g., polydimethylsiloxane), polysulfone, polyimide, polyacetic anhydride, polyurea, polysulfide, polyphosphazene, polyketone polyphenylene, and polyhaloolefin. These polymers can be optionally copolymerized or can be modified ones.

For the polymer for use as the axial molecule in the present invention, polyethylene glycol, polyisoprene, polyisobutylene, polybutadiene, polypropylene glycol, polytetrahydrofuran, polydimethylsiloxane, polyethylene, polypropylene, polyvinyl alcohol or polyvinyl methyl ether is preferred, and polyethylene glycol is most preferred.

The molecular weight of the polymer for use as the axial molecule is not specifically limited, but if too large, a viscosity may increase when the polymer is mixed with any other polymerizable monomer, and if so, not only the polymer is difficult to handle but also the compatibility thereof may worsen. From such viewpoints, the weight-average molecular weight Mw of the axial molecule is preferably within a range of 400 to 100000, more preferably 1000 to 50000, even more preferably 2000 to 30000. The weight-average molecular weight Mw is a value measured according to the gel permeation chromatography (GPC) measurement method described in the section of Examples to be given hereinunder.

Preferably the polymer for use for the axial molecule has a bulky group at both ends so that the axial molecule passing through the ring of a cyclic molecule does not drop off. The bulky group to be formed at both ends of the polymer for use for the axial molecule is not specifically limited so far as the group can prevent a cyclic molecule from dropping out of the axial molecule. From the viewpoint of bulkiness, the group includes an adamantyl group, a trityl group, a fluoresceinyl group, a dinitrophenyl group and a pyrenyl group, and especially from the viewpoint of ease of introduction, an adamantyl group is preferred.

On the other hand, the cyclic molecule of the polyrotaxane monomer (A) for use in the present invention may be any one having a ring sized to encapsulate the axial molecule, and such a ring includes a cyclodextrin ring, a crown ether ring, a benzocrown ring, a dibenzocrown ring, and a dicyclohexanocrown ring, and is especially preferably a cyclodextrin ring.

The cyclodextrin ring includes an α-form (ring inner diameter 0.45 to 0.6 nm), a β-form (ring inner diameter 0.6 to 0.8 nm) and a γ-form (ring inner diameter 0.8 to 0.95 nm). A mixture of these can also be used. In the present invention, an α-cyclodextrin ring and a 6-cyclodextrin ring are preferred, and an α-cyclodextrin ring is most preferred.

Regarding the cyclic molecule, at least one cyclic molecule encapsulates one axial molecule. When the maximum encapsulation number of the cyclic molecules capable of encapsulating one axial molecule is 1.0, the encapsulation number of cyclic molecules is preferably at most 0.8 or less. If the encapsulation number of cyclic molecules is too large, cyclic molecules densely exist relative to one axial molecule. As a result, the slidability (slide width) tends to lower. In addition, the molecular weight of the polyrotaxane monomer itself increases. Consequently in the case where such a polyrotaxane monomer is used in a polymerizable composition, the handleability of the polymerizable composition tends to worsen. Therefore, more preferably one axial molecule is encapsulated by at least 2 or more cyclic molecules, and the encapsulation number of cyclic molecules falls within a range of at most 0.5 or less.

The maximum encapsulation number of cyclic molecules relative to one axial molecule can be calculated from the length of the axial molecule and the thickness of the ring of the cyclic molecule. For example, in a case where the chain part of the axial molecule is formed of polyethylene glycol and the cyclic molecule is an α-cyclodextrin ring, the maximum encapsulation number is calculated as follows. Specifically two repeating units of polyethylene glycol [—CH2-CH2O-] approximate the thickness of one α-cyclodextrin ring. Therefore, the repeating unit number is calculated from the molecular weight of polyethylene glycol, and ½ of the repeating unit number corresponds to the maximum encapsulation number of the cyclic molecules. The maximum encapsulation number is 1.0, and the encapsulation number of cyclic molecules is controlled to fall within the above-mentioned range.

The cyclic molecules can be used singly, or plural kinds thereof can be used as combined.

Preferably the cyclic molecule has the polymerizable functional group of the polyrotaxane monomer (A) for use in the present invention. With that, the sliding effect of the cyclic molecules that is a characteristic feature of polyrotaxane can be sufficiently expressed, and excellent mechanical characteristics can be expressed.

Not specifically limited, the polymerizable functional group can be any group capable of polymerizing with any other polymerizable monomer. Above all, a polymerizable functional group favorable for use in the present invention is at least one group selected from the group consisting of a hydroxy group and an amino group. Having such a polymerizable functional group, the polyrotaxane monomer (A) can be introduced into a urethane(urea) resin, a melamine resin, a urea resin or an amide resin to be mentioned hereinunder.

Regarding the polymerizable functional group in the cyclic molecule, when the cyclic molecule is a cyclodextrin ring, the hydroxy group of the ring can be used as the polymerizable functional group. The hydroxy group of the cyclodextrin ring can be converted into an amino group in a known method. For example, a cyclodextrin derivative in which the hydroxy group has been sulfonated is reacted with a sodium azide, and finally the azide group is reduced with triphenyl phosphine to introduce an amino group into the derivative (see Nanomaterial Cyclodextrin (edited by the Society of Cyclodextrin, published by Yoneda Publishing)).

In order that the polyrotaxane moiety can be introduced into the resin to exhibit an excellent effect of the polyrotaxane monomer (A), the number of the polymerizable functional groups is not specifically limited so far as at least two such groups are introduced.

In consideration of controlling the compatibility with the polymerizable monomer (B) for expressing more excellent characteristics of the polyrotaxane monomer (A) for use in the present invention, preferably side chains are introduced into the cyclic molecule.

Further, in the case where the polyrotaxane monomer (A) has side chains, also preferably the side chain has a polymerizable functional group. With that, the polyrotaxane monomer (A) can bond to the polymerizable monomer (B) via the side chain and can therefore express more excellent characteristics.

Not specifically limited, the side chain is preferably formed of a repetition of an organic chain having 3 to 20 carbon atoms. Those differing in the kind of side chains and in the number-average molecular weight thereof can be introduced into the cyclic molecule. The number-average molecular weight of the side chains is preferably 5000 or less, more preferably within a range of 45 to 5,000, even more preferably 55 to 3,000, further more preferably 100 to 1,500. The number-average molecular weight of the side chains can be controlled by the amount of the substance to be used in introducing the side chains and can be determined by calculation. In the case of determining it from the resultant polyrotaxane monomer (A), the molecular weight can be measured in ¹H-NMR.

By determining the number-average molecular weight of side chains to be not less than the above-mentioned lower limit, contribution to improvement of characteristics is greater. On the other hand, by determining the number-average molecular weight of side chains to be not more than the above-mentioned upper limit, handleability betters and the yield of hollow microballoons improves.

In general, utilizing the reactive functional group that the cyclic molecule has, the side chains are introduced by modifying the reactive functional group. In particular, in the present invention, the polyrotaxane monomer (A) is preferably such that the cyclic molecule has a hydroxy group and side chains are introduced by modifying the hydroxy group. For example, an α-cyclodextrin ring has 18 hydroxy groups as reactive functional groups. Side chains may be introduced by modifying the hydroxy groups. Specifically at most 18 side chains can be introduced to one α-cyclodextrin ring.

For fully exhibiting the function of the side chains, preferably 4 to 70% of all the reactive functional groups that the cyclic molecule has (hereinafter this value may be referred to as a modification degree) are modified with side chains. The modification degree is an average value.

As described in detail hereinunder, the reactivity of the reactive functional group (for example, a hydroxy group) of the cyclic molecule is lower than that of the reactive functional group (for example, a hydroxy group) that the side chains have. Therefore, even when the modification degree is not 100%, a more excellent effect can be exhibited so far as it falls within the above range.

In the present invention, where a hydroxy group corresponds to the polymerizable functional group, the case is considered as follows. For example, when the cyclic molecule is a cyclodextrin ring and in the case where a side chain is not introduced into the hydroxy group that the cyclodextrin ring has, the hydroxy group of the case is also considered as a polymerizable functional group. In this connection, in the case where side chains bond to 9 of 18 OH groups of the above-mentioned α-cyclodextrin ring, the modification degree in the case is 50%.

In the present invention, the side chains may be linear or branched so far as the molecular weight thereof falls within the above-mentioned range. For introduction of side chains, a known method may be appropriately employed, and for example, methods and compounds disclosed in WO2015/159875A can be appropriately used. Specifically, ring-cleavage polymerization; radical polymerization; cationic polymerization; anionic polymerization; and living radical polymerization such as atom transfer radical polymerization, RAFT polymerization or NMP polymerization can be utilized. According to the method, a suitably selected compound may be reacted with the reactive functional group that the cyclic molecule has to introduce a side chain of an appropriate size.

For example, by ring-cleavage polymerization, a side chain derived from a cyclic compound such as a cyclic ether, a cyclic siloxane, a cyclic lactone, a cyclic lactam, a cyclic acetal, a cyclic amine, a cyclic carbonate, a cyclic iminoether or a cyclic thiocarbonate can be introduced.

Among the cyclic compounds, from the viewpoint of high reactivity and easiness in size control (molecular weight), a cyclic ether, a cyclic lactone and a cyclic lactam are preferably used. For side chains introduced by ring-cleavage polymerization of a cyclic compound such as a cyclic lactone or a cyclic ether, a hydroxy group is introduced into the terminal of the side chain; and for side chains introduced by ring-cleavage polymerization of a cyclic lactam, an amino group is introduced into the terminal of the side chain. Preferred cyclic ethers and cyclic lactones are disclosed in WO02015/159875A.

Above all, preferred cyclic lactams in the present invention are:

a 4-membered lactam such as 4-benzoyloxy-2-azetidinone,

a 5-membered lactam such as γ-butyrolactam, 2-azabicyclo(2,2,1)hept-5-en-3-one and 5-methyl-2-pyrrolidone,

a 6-membered lactam such as 2-piperidone-3-ethyl carbonate,

a 7-membered lactam such as ε-caprolactam, DL-α-amino-ε caprolactam, and

ω-heptalactam. Especially preferred are ε-caprolactam, γ-butyrolactam and DL-α-amino-ε caprolactam, and more preferred is ε-caprolactam.

In the present invention, preferred cyclic lactones are ε-caprolactone, α-acetyl-γ-butyrolactone, α-methyl-γ-butyrolactone, γ-valerolactone and γ-butyrolactone. Most preferred is ε-caprolactone.

In the case where side chains are introduced by reacting a cyclic compound through ring-cleavage polymerization, the reactive functional group (for example, a hydroxy group) of the cyclic molecule is poorly reactive and therefore, in particular, direct reaction of large molecules would be difficult owing to steric hindrance. In such a case, for example, for reacting the above-mentioned caprolactone, a low-molecular compound such as propylene oxide is once reacted with the reactive functional group of the cyclic molecule for hydroxypropylation, and then a highly reactive functional group is introduced. Subsequently side chains are introduced by ring-cleavage polymerization using the above-mentioned cyclic compound. In the case, the method can be employed, and in the case, the hydroxypropylated moiety can also be considered as a side chain.

In addition to the above, a side chain having a polymerizable functional group such as a hydroxy group or an amino group can be introduced by introducing a side chain derived from a cyclic compound, such as the above-mentioned cyclic acetal, cyclic amine, cyclic carbonate or cyclic iminoether through ring-cleavage polymerization. Specific examples of these cyclic compounds are described in WO2015/068798A.

A method of introducing side chains into a cyclic molecule by radical polymerization is as follows. Some cyclic molecules may not have an active site to be a radical starting point. In such cases, prior to reacting with a radical polymerizable compound, a compound for forming a radical starting point in the functional group (for example, a hydroxy group) that the cyclic molecule has need to be reacted to form an active site to be a radical starting point.

The compound for forming a radical starting point is typically an organic halogen compound. Examples thereof include 2-bromoisobutyryl bromide, 2-bromobutyric acid, 2-bromopropionic acid, 2-chloropropionic acid, 2-bromoisobutyric acid, epichlorohydrin, epibromohydrin, and 2-chloroethyl isocyanate. Specifically such an organic halogen compound reacts with the functional group that a cyclic molecule has to bond to the cyclic molecule, whereby a halogen atom-containing group (organic halogen compound residue) is introduced into the cyclic molecule. The organic halogen compound residue forms a radical by halogen atom transfer in radical polymerization, and this acts as a radical polymerization starting point to boost radical polymerization.

The organic halogen compound residue can also be introduced, for example, by reacting a compound having a functional group such as an amine, an isocyanate or an imidazole with the hydroxy group that the cyclic molecule has to thereby introduce a functional group other than a hydroxy group, followed by reacting the above-mentioned organic halogen compound with the other functional group for introduction of the residue.

The radical polymerizable compound for use for introducing side chains by radical polymerization is preferably an ethylenically unsaturated bond-having compound, for example, a compound having at least one functional group such as a (meth)acrylate group, a vinyl group and a styryl group (hereinafter this may also be referred to as ethylenically unsaturated monomer). As the ethylenically unsaturated monomer, also usable is an oligomer or polymer having a terminal ethylenically unsaturated bond (hereinafter this may also be referred to as macromonomer). Specific examples of such preferred ethylenically unsaturated monomers are described in WO2015/068798A, and these are usable here.

In the present invention, reaction of a side chain functional group with any other compound to introduce a structure derived from the other compound may be referred to as “modification”. Regarding the compound for modification, in particular, a compound reactive with the function group of a side chain can be used. By selecting the compound, various polymerizable functional groups can be introduced into side chains, or side chains can be modified into a group not having polymerizability.

As understood from the above description, the side chains to be introduced into the cyclic molecule may have various functional groups other than polymerizable functional groups.

Further, depending on the kind of the functional group that the compound for side chain introduction has, a part of the side chains may bond to the functional group of the ring of the cyclic molecule that other axial molecules have to form a crosslinked structure.

As described above, the polymerizable functional group of the polyrotaxane monomer (A) is preferably one that the above-mentioned cyclic molecule has, or one that the side chain introduced into the cyclic molecule has. Above all, in consideration of reactivity, it is preferable that the terminal of the side chain is a polymerizable functional group, and more preferably two or more polymerizable functional groups are introduced into the terminal of the side chains per molecule of the polyrotaxane monomer (A). The upper limit of the number of the polymerizable functional groups is not specifically limited, but above all, regarding the upper limit of the number of the polymerizable functional groups, a value calculated by dividing the molar number of the polymerizable functional groups introduced into the terminal of the side chains by the weight-average molecular weight (Mw) of the polyrotaxane monomer (A) (hereinafter the value may be referred to as a polymerizable functional group content) is preferably 10 mmol/g or less. As described above, the polymerizable functional group content is a value calculated by dividing the molar number of the polymerizable functional groups introduced into the terminal of the side chains by the weight-average molecular weight (Mw) of the polyrotaxane monomer (A), in other words, the content indicates the molar number of the polymerizable functional group introduced into the terminal of the side chain per gram of the polyrotaxane monomer (A).

The polymerizable functional group content is preferably 0.2 to 8 mmol/g, more preferably 0.5 to 5 mmol/g. The weight-average molecular weight is a value measured through gel permeation chromatography (GPC) described in the section of Examples.

The content of the total polymerizable functional groups of the polymerizable functional group not introduced into the side chain and the polymerizable functional group introduced into the side chain preferably falls with the following range. Specifically the content of the total polymerizable functional groups is preferably 0.2 to 20 mmol/g. More preferably the content of the total polymerizable functional groups is 0.4 to 1.6 mmol/g, even more preferably 1 to 10 mmol/g. The content of the total polymerizable functional groups is a value calculated by dividing the total of the molar number of the polymerizable functional group not introduced into the side chain and the molar number of the polymerizable functional group introduced into the side chain by the weight-average molecular weight (Mw) of the polyrotaxane monomer (A).

The molar number of the polymerizable functional group and the total polymerizable functional groups described in the above is an average value.

The polyrotaxane monomer (A) most favorably used in the present invention is composed of a polyethylene glycol bonding to the both ends via an adamantyl group as an axial molecule and an α-cyclodextrin ring as a cyclic molecule, in which, preferably a hydroxy group or an amino group is introduced onto the cyclic molecule as a polymerizable functional group, and more preferably hydroxy group-terminated side chains are introduced into the cyclic molecule by ring-cleavage polymerization of ε-caprolactone, or amino group-terminated side chains are introduced into the cyclic molecule by ring-cleavage polymerization of ε-caprolactam. In this case, the side chains may be introduced by ring-cleavage polymerization of ε-caprolactone or ε-caprolactam after the hydroxy group of the α-cyclodextrin ring has been hydroxypropylated, or may be introduced by ring-cleavage polymerization of ε-caprolactam after the hydroxy group of the α-cyclodextrin ring has been modified into an amino group.

With that, all the introduced side chains can be terminated with a hydroxy group or an amino group, or for the purpose of controlling the molar number of the hydroxy group or the amino group to be a desired one, the terminal can be modified into a non-reactive group.

In the present invention, the affinity of the polyrotaxane monomer (A) for an aqueous phase or an oily phase varies depending on the cyclic molecule used or the side chains as mentioned above.

In the present invention, the hydrophilicity of the polyrotaxane monomer (A) is a case where the monomer is at least partially soluble in water and has a higher affinity in an aqueous phase than in an oily phase, and the oleophilicity of the polyrotaxane monomer (A) is a case where the monomer is at least partially soluble in an organic solvent and has a higher affinity in an oily phase than in an aqueous phase. For example, in the case where the solubility in water at room temperature of the component (A) is at least 20 g/l or more, the component (A) is hydrophilic, and in the case where the solubility thereof in an organic solvent solution not soluble in water is 20 g/l or more, the component (A) is oleophilic.

<(B) Polymerizable Monomer Other than Polyrotaxane Monomer Having at Least Two Polymerizable Functional Groups in the Molecule>

The (B) polymerizable monomer other than polyrotaxane monomer having at least two polymerizable functional groups in the molecule is not specifically limited so far as it is polymerizable with the polymerizable functional group of the component (A), and above all, preferred is at least one selected from the group consisting of (B1) a polyfunctional isocyanate compound having at least two isocyanate groups (hereinunder this may be referred to as polyfunctional isocyanate compound (B1), or component (B1)), (B2) a polyol compound having at least two hydroxy groups (hereinunder this may be referred to as polyol compound (B2), or component (B2)), (B3) a polyfunctional amino compound having at least two amino groups (hereinunder this may be referred to as polyfunctional amine compound (B3), or component (B3)), (B4) a compound at least having both a hydroxy group and an amino group (hereinafter this may be referred to as component (B4)), (B5) a melamine-formaldehyde prepolymer compound (hereinafter this may be referred to as component (B5)), (B6) a urea-formaldehyde prepolymer compound (hereinafter this may be referred to as component (B6), and (B7) a polyfunctional carboxylic acid compound having at least two carboxy groups (hereinafter this may be referred to as polyfunctional carboxylic acid compound (B7), or component (B7)).

The hollow microballoons of the present invention are hollow microballoons comprising a resin produced by polymerizing a polymerizable composition that contains the above-mentioned polyrotaxane monomer (A) and polymerizable monomer (B). By selecting the component (A) and the component (B), the resin for the hollow microballoons can be selected. Above all, the resin for the hollow microballoons of the present invention is preferably at least one resin selected from the group consisting of a urethane(urea) resin, a melamine resin, a urea resin or an amide resin, and a copolymer resin of two of more of these resins.

In the present invention, the urethane(urea) resin is a resin produced by reaction of an isocyanate group and a hydroxy group and/or an amino group and having a urethane bond in the main chain, a resin having a urea bond in the main chain, or a resin having both a urethane bond and a urea bond in the main chain, the melamine resin is a resin in which the main chain is formed by polycondensation of a polyfunctional amine containing melamine and formaldehyde, the urea resin is a resin where the main chain is formed by polycondensation of urea (further including a polyfunctional amine) and formaldehyde, and the amide resin is a resin having an amide bond in the main chain.

Among these, the urethane(urea) resin is most preferred in the present invention.

Regarding the combination of the polyrotaxane monomer (A) and the polymerizable monomer (B), for example, in the case where the hollow microballoons are formed of a urethane(urea) resin, the polymerizable functional group of the polyrotaxane monomer (A) is a hydroxy group and/or an amino group, and the polymerizable monomer (B) indispensably contains (B1) a polyfunctional isocyanate compound and may additionally contain (B2) a polyol compound having at least two hydroxy groups, (B3) a polyfunctional amine compound having at least two amino groups, or (B4) a compound at least having both a hydroxy group and an amino group.

In the case where the hollow microballoons are formed of a melamine resin, an amino group is selected for the polymerizable functional group of the polyrotaxane monomer (A), and a melamine-formaldehyde prepolymer compound (B5) is selected for the polymerizable monomer (B).

In the case where the hollow microballoons are formed of a urea resin, an amino group is selected for the polymerizable functional group of the polyrotaxane monomer (A), and a urea-formaldehyde prepolymer compound (B6) is selected for the polymerizable monomer (B).

In the case where the hollow microballoons are formed of an amide resin, the polymerizable functional group of the polyrotaxane monomer (A) is an amino group, and the polymerizable monomer (B) indispensably contains (B7) a polyfunctional carboxylic acid compound having at least two carboxy groups and, in addition to this, may contain (B3) a polyfunctional amino compound having at least two amino groups.

Hereinunder specific examples of the (B) polymerizable monomer other than the polyrotaxane monomer having at least two polymerizable functional groups in the molecule are described.

### <(B1) Polyfunctional Isocyanate Compound Having at Least Two Isocyanate Groups>

The polyfunctional isocyanate compound (B1) for use in the present invention may be any one with no limitation, so far as it is a polyfunctional isocyanate compound having at least two isocyanate groups. Above all, a compound having 2 to 6 isocyanate groups in the molecule is preferred, and a compound having 2 to 3 isocyanate groups is more preferred.

The component (B1) may be (B12) a urethane prepolymer containing an unreacted isocyanate group prepared by reaction of a difunctional isocyanate compound to be mentioned below and a difunctional polyol compound or a difunctional amine compound (hereinafter this may be referred to as urethane prepolymer (B12), or component (B12)). Any one containing an unreacted isocyanate group can be used with no limitation for the urethane prepolymer (B12).

The component (B1) can be broadly grouped into an aliphatic isocyanate, an alicyclic isocyanate, an aromatic isocyanate, other isocyanate, and the urethane prepolymer (B12). For the component (B1), one kind of compound can be used, or plural kinds of compounds can be used. In the case where plural kinds of compounds are sued, the basis mass is a total compound of the plural kinds of compounds. Specific examples of the isocyanate compounds are listed below.

### (Aliphatic Isocyanate)

A difunctional isocyanate monomer (corresponding to a difunctional polyisocyanate compound constituting a urethane prepolymer), such as ethylene diisocyanate, trimethylene diisocyanate, tetramethylene diisocyanate, hexamethylene diisocyanate, octamethylene diisocyanate, nonamethylene diisocyanate, 2,2′-dimethylpentane diisocyanate, 2,2,4-trimethylhexamethylene diisocyanate, decamethylene diisocyanate, butene diisocyanate, 1,3-butadiene 1,4-diisocyanate, 2,4,4-trimethylhexamethylene diisocyanate, 1,6,11-trimethylundecamethylene diisocyanate, 1,3,6-trimethylhexamethylene diisocyanate, 1,8-diisocyanate 4-isocyanate methyloctane, 2,5,7-trimethyl-1,8-diisocyanate 5-isocyanate methyloctane, bis(isocyanatoethyl) carbonate, bis(isocyanatoethyl) ether, 1,4-butylene glycol dipropyl ether-ω,ω′-diisocyanate, lysine diisocyanate methyl ester, and 2,4,4-trimethylhexamethylene diisocyanate.

### (Alicyclic Isocyanate)

A difunctional isocyanate monomer (corresponding to a difunctional polyisocyanate compound constituting a urethane prepolymer), such as isophorone diisocyanate, (bicyclo[2.2.1]heptane-2,5-diyl)bismethylene diisocyanate, (bicyclo[2.2.1]heptane-2,6-diyl)bismethylene diisocyanate, 2β,5α-bis(isocyanate)norbornane, 2β,5β-bis(isocyanate)norbornane, 2β,6α-bis(isocyanate)norbornane, 2β,6β-bis(isocyanate)norbornane, 2,6-(diisocyanatomethyl)furan, 1,3-bis(isocyanatomethyl)cyclohexane, dicyclohexylmethane-4,4′-diisocyanate, 4,4-isopropylidene-bis(cyclohexyl isocyanate), cyclohexane diisocyanate, methylcyclohexane diisocyanate, dicyclohexyldimethylmethane diisocyanate, 2,2′-dimethyldicyclohexylmethane diisocyanate, bis(4-isocyanate-n-butylidene)pentaerythritol, dimer acid diisocyanate, 2,5-bis(isocyanatomethyl)-bicyclo[2,2,1]-heptane, 2,6-bis(diisocyanatomethyl)-bicyclo[2,2,1]-heptane, 3,8-bis(isocyanatomethyl)tricyclodecane, 3,9-bis(isocyanatomethyl)tricyclodecane, 4,8-bis(isocyanatomethyl)tricyclodecane, 4,9-bis(isocyanatomethyl)tricyclodexane, 1,5-diisocyanatedecalin, 2,7-diisocyanatedecalin, 1,4-diisocyanatedecalin, 2,6-diisocyanatedecalin, bicyclo[4.3.0]nonane-3,7-diisocyanate, bicyclo[4.3.0]nonane-4,8-diisocyanate, bicyclo[2.2.1]heptane-2,5-diisocyanate, bicyclo[2.2.1]heptane-2,6-diisocyanate, bicyclo[2,2,2]octane-2,5-diisocyanate, bicyclo[2,2,2]octane-2,6-diisocyanate, tricyclo[5.2.1.02.6]decane-3,8-diisocyanate, and tricyclo[5.2.1.02.6]decane-4,9-diisocyanate, and a polyfunctional isocyanate monomer such as 2-isocyanatomethyl-3-(3-isocyanatopropyl)-5-isocyanatomethyl-bicyclo[2,2,1]-heptane, 2-isocyanatomethyl-3-(3-isocyanatopropyl)-6-isocyanatomethyl-bicyclo[2,2,1]-heptane, 2-isocyanatomethyl-2-(3-isocyanatopropyl)-5-isocyanatomethyl-bicyclo[2,2,1]-heptane, 2-isocyanatomethyl-2-(3-isocyanatopropyl)-6-isocyanatomethyl-bicyclo[2,2,1]-heptane, 2-isocyanatomethyl-3-(3-isocyanatopropyl)-5-(2-isocyanatoethyl)-bicyclo[2,2,1]-heptane, 2-isocyanatomethyl-3-(3-isocyanatopropyl)-6-(2-isocyanatoethyl)bicyclo[2,2,1]-heptane, 2-isocyanatomethyl-2-(3-isocyanatopropyl)-5-(2-isocyanatoethyl)-bicyclo[2,2,1]heptane, 2-isocyanatomethyl-2-(3-isocyanatopropyl)-6-(2-isocyanatoethyl)-bicyclo[2,2,1]-heptane, and 1,3,5-tris(isocyanatomethyl)cyclohexane.

### (Aromatic Isocyanate)

A difunctional isocyanate monomer (corresponding to a difunctional polyisocyanate compound constituting a urethane prepolymer) such as xylylene diisocyanate (o-, m-, p-), tetrachloro-m-xylylene diisocyanate, methylenediphenyl-4,4′-diisocyanate, 4-chloro-m-xylylene diisocyanate, 4,5-dichloro-m-xylylene diisocyanate, 2,3,5,6-tetrabromo-p-xylylene diisocyanate, 4-methyl-m-xylylene diisocyanate, 4-ethyl-m-xylylene diisocyanate, bis(isocyanatoethyl)benzene, bis(isocyanatopropyl)benzene, 1,3-bis(α,α-dimethylisocyanatomethyl)benzene, 1,4-bis(α,α-dimethylisocyanatomethyl)benzene, α,α,α′,α′-tetramethylxylylene diisocyanate, bis(isocyanatobutyl)benzene, bis(isocyanatomethyl)naphthalene, bis(isocyanatomethyl)diphenyl ether, bis(isocyanatoethyl) phthalate, 2,6-diisocyanatomethyl)furan, phenylene diisocyanate (o-, m-, p-), ethylphenylene diisocyanate, isopropylphenylene diisocyanate, dimethylphenylene diisocyanate, diethylphenylene diisocyanate, diisopropylphenylene diisocyanate, trimethylbenzene triisocyanate, benzene triisocyanate, 1,3,5-triisocyanatomethylbenzene, 1,5-naphthalene diisocyanate, methylnaphthalene diisocyanate, biphenyl diisocyanate, 2,4-tolylene diisocyanate, 2,6-tolylene diisocyanate, 4,4′-diphenylmethane diisocyanate, 2,2′-diphenylmethane diisocyanate, 2,4′-diphenylmethane diisocyanate, 3,3′-dimethyldiphenylmethane-4,4′-diisocyanate, bibenzyl-4,4′-diisocyanate, bis(isocyanatophenyl)ethylene, 3,3′-dimethoxybiphenyl-4,4′-diisocyanate, phenylisocyanatomethyl isocyanate, phenylisocyanatoethyl isocyanate, tetrahydronaphthalene diisocyanate, hexahydrobenzene diisocyanate, hexahydrodiphenylmethane-4,4′-diisocyanate, diphenyl ether diisocyanate, ethylene glycol diphenyl ether diisocyanate, 1,3-propylene glycol diphenyl ether diisocyanate, benzophenone diisocyanate, diethylene glycol diphenyl ether diisocyanate, dibenzofuran diisocyanate, carbazole diisocyanate, ethylcarbazole diisocyanate, dichlorocarbazole diisocyanate, 2,4-tolylene diisocyanate, and 2,6-tolylene diisocyanate.

A polyfunctional isocyanate monomer, such as mesitylene triisocyanate, triphenylmethane triisocyanate, polymeric MDI, naphthalene triisocyanate, diphenylmthane-2,4,4′-triisocyanate, 3-methyl-diphenylmethane-4,4′,6-triisocyanate, and 4-methyl-diphenylmethane-2,3,4′,5,6-pentaisocyanate.

### (Other Isocyanate)

The other isocyanate includes a polyfunctional isocyanate having a biuret structure, a uretdione structure or an isocyanurate structure, for which diisocyanates such as hexamethylene diisocyanate or tolylene diisocyanate are main materials (for example, JP2004-534870A discloses a method for modifying a biuret structure, a uretdione structure or an isocyanurate structure of an aliphatic polyisocyanate), and a polyfunctional isocyanate as an adduct with a tri- or higher polyol such as trimethylolpropane (as disclosed in a document (Polyurethane Resin Handbook, edited by Keiji Iwata, published by Nikkan Kogyo Shimbun Co. (1987)).

### ((B12) Urethane Prepolymer)

In the present invention, as the urethane prepolymer (B12), preferred are those produced by reacting a difunctional isocyanate compound selected from the component (B1) (compound exemplified as the component (B1)), and (B21) a difunctional polyol compound or (B31) a difunctional amine compound shown below.

Examples of the difunctional polyol compound (B21) are listed below.

### ((B21) Difunctional Polyol)

### (Aliphatic Alcohol)

A difunctional polyol compound, such as ethylene glycol, diethylene glycol, propylene glycol, dipropylene glycol, butylene glycol, 1,5-dihydroxypentane, 1,6-dihydroxyhexane, 1,7-dihydroxyheptane, 1,8-dihydroxyoctane, 1,9-dihydroxynonane, 1,10-dihydroxydecane, 1,11-dihydroxyundecane, 1,12-dihydroxydodecane, neopentyl glycol, glyceryl monooleate, monoelaidin, polyethylene glycol, 3-methyl-1,5-dihydroxypentane, dihydroxyneopentyl, 2-ethyl-1,2-dihydroxyhexane, 2-methyl-1,3-dihydroxypropane, polyester polyol (a compound having a hydroxy group at both ends obtained by condensation of a polyol and a polybasic acid), polyether polyol (a compound obtained by ring-cleavage polymerization of an alkylene oxide, or a compound obtained by reaction of a compound having at least two active hydrogen-containing groups in the molecule and an alkylene oxide and a modified derivative thereof, having a hydroxy group at both ends of the molecule), polycaprolactone polyol (a compound obtained by ring-cleavage polymerization of ε-caprolactone, having a hydroxy group at both ends of the molecule), polycarbonate polyol (a compound obtained by phosgenation of at least one low-molecular polyol or a compound obtained by interesterification with ethylene carbonate, diethyl carbonate or diphenyl carbonate, having a hydroxy group at both ends of the molecule), and polyacryl polyol (a polyol compound obtained by polymerization of a (meth)acrylate or vinyl monomer, having a hydroxy group at both ends of the molecule).

### (Alicyclic Alcohol)

A difunctional polyol compound, such as hydrogenated bisphenol A, cyclobutanediol, cyclopentanediol, cyclohexanediol, cycloheptanediol, cyclooctanediol, cyclohexanedimethanol, hydroxypropylcyclohexanol, tricyclo[5,2,1,02,6]decane-dimethanol, bicyclo[4,3,0]-nonanediol, dicyclohexanediol, tricyclo[5,3,1,13,9]dodecanediol, bicyclo[4,3,0]nonanedimethanol, tricyclo[5,3,1,13,9]dodecane-diethanol, hydroxypropyltricyclo[5,3,1,13,9]dodecanol, spiro[3,4]octanediol, butylcyclohexanediol, 1,1′-bicyclohexylidenediol, 1,4-cyclohexanedimethanol, 1,3-cyclohexanedimethanol, 1,2-cyclohexanedimethanol, and o-dihydroxyxylylene.

### (Aromatic Alcohol)

A difunctional polyol compound, such as dihydroxynaphthalene, dihydroxybenzenes, bisphenol A, bisphenol F, xylylene glycol, tetrabromobisphenol A, bis(4-hydroxyphenyl)methane, 1,1-bis(4-hydroxyphenyl)ethane, 1,2-bis(4-hydroxyphenyl)ethane, bis(4-hydroxyphenyl)phenylmethane, bis(4-hydroxyphenyl)diphenylmethane, bis(4-hydroxyphenyl)-1-naphthylmethane, 1,1-bis(4-hydroxyphenyl)-1-phenylethane, 2-(4-hydroxyphenyl)-2-(3-hydroxyphenyl)propane, 2,2-bis(4-hydroxyphenyl)butane, 1,1-bis(4-hydroxyphenyl)butane, 2,2-bis(4-hydroxyphenyl)-3-methylbutane, 2,2-bis(4-hydroxyphenyl)pentane, 3,3-bis(4-hydroxyphenyl)pentane, 2,2-bis(4-hydroxyphenyl)hexane, 2,2-bis(4-hydroxyphenyl)octane, 2,2-bis(4-hydroxyphenyl)-4-methylpentane, 2,2-bis(4-hydroxyphenyl)heptane, 4,4-bis(4-hydroxyphenyl)heptane, 2,2-bis(4-hydroxyphenyl)tridecane, 2,2-bis(4-hydroxyphenyl)octane, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-tert-butyl-4-hydroxyphenyl)propane, 2,2-bis(3-cyclohexyl-4-hydroxyphenyl)propane, 2,2-bis(3-allyl-4′-hydroxyphenyl)propane, 2,2-bis(3-methoxy-4-hydroxyphenyl)propane, 2,2-bis(3,5-dimethyl-4-hydroxyphenyl)propane, 2,2-bis(2,3,5,6-tetramethyl-4-hydroxyphenyl)propane, bis(4-hydroxyphenyl)cyanomethane, 1-cyano-3,3-bis(4-hydroxyphenyl)butane, 2,2-bis(4-hydroxyphenyl)hexafluoropropane, 1,1-bis(4-hydroxyphenyl)cyclopentane, 1,1-bis(4-hydroxyphenyl)cyclohexane, 1,1-bis(4-hydroxyphenyl)cycloheptane, 1,1-bis(3-methyl-4-hydroxyphenyl)cyclohexane, 1,1-bis(3,5-dimethyl-4-hydroxyphenyl)cyclohexane, 1,1-bis(3,5-dichloro-4-hydroxyphenyl)cyclohexane, 1,1-bis(3-methyl-4-hydroxyphenyl)-4-methylcyclohexane, 1,1-bis(4-hydroxyphenyl)-3,3,5-trimethylcyclohexane, 2,2-bis(4-hydroxyphenyl)norbornane, 2,2-bis(4-hydroxyphenyl)adamantane, 4,4′-dihydroxydiphenyl ether, 4,4′-dihydroxy-3,3′-dimethyldiphenyl ether, ethylene glycol bis(4-hydroxyphenyl) ether, 4,4′-dihydroxydiphenyl sulfide, 3,3′-dimethyl-4,4′-dihydroxydiphenyl sulfide, 3,3′-dicyclohexyl-4,4′-dihydroxydiphenyl sulfide, 3,3′-diphenyl-4,4′-dihydroxydiphenyl sulfide, 4,4′-dihydroxydiphenyl sulfoxide, 3,3′-dimethyl-4,4′-dihydroxydiphenyl sulfoxide, 4,4′-dihydroxydiphenyl sulfone, 4,4′-dihydroxy-3,3′-dimethyldiphenyl sulfone, bis(4-hydroxyphenyl) ketone, bis(4-hydroxy-3-methylphenyl) ketone, 7,7′-dihydroxy-3,3′,4,4′-tetrahydro-4,4,4′,4′-tetramethyl-2,2′-spirobi(2H-1-benzopyran), trans-2,3-bis(4-hydroxyphenyl)-2-butane, 9,9-bis(4-hydroxyphenyl)fluorene, 3,3-bis(4-hydroxyphenyl)-2-butanone, 1,6-bis(4-hydroxyphenyl)-1,6-hexanedione, 4,4′-dihydroxybiphenyl, m-dihydroxyxylylene, p-dihydroxyxylylene, 1,4-bis(2-hydroxyethyl)benzene, 1,4-bis(3-hydroxypropyl)benzene, 1,4-bis(4-hydroxybutyl)benzene, 1,4-bis(5-hydroxypentyl)benzene, 1,4-bis(6-hydroxyhexyl)benzene, 2,2-bis[4-(2″-hydroxyethyloxy)phenyl]propane, hydroquinone and resorcin.

### (Polyester Diol)

This includes a difunctional polyol compound obtained by condensation of a polyol and a polybasic acid. Above all, the number-average molecular weight thereof is preferably 400 to 2000, more preferably 500 to 1500, most preferably 600 to 1200.

### (Polyether Diol)

This includes a difunctional polyol compound obtained by ring-cleavage polymerization of an alkylene oxide or reaction of a compound having at least two active hydrogen-containing groups in the molecule and an alkylene oxide, or a modified derivative thereof. Above all, the number-average molecular weight thereof is preferably 400 to 2000, more preferably 500 to 1500, most preferably 600 to 1200.

### (Polycaprolactone Polyol)

This includes a difunctional polyol compound obtained by ring-cleavage polymerization of ε-caprolactone. Above all, the number-average molecular weight thereof is preferably 400 to 2000, more preferably 500 to 1500, most preferably 600 to 1200.

### (Polycarbonate Polyol)

This includes a difunctional polyol compound obtained by phosgenation of at least one low-molecular polyol, or a difunctional polyol compound obtained by interesterification with ethylene carbonate, diethyl carbonate or diphenyl carbonate. Above all, the number-average molecular weight thereof is preferably 400 to 2000, more preferably 500 to 1500, most preferably 600 to 1200.

### (Polyacryl Polyol)

This includes a difunctional polyol compound obtained by polymerization of a (meth)acrylate or vinyl monomer.

### ((B31) Difunctional Amine Compound)

Examples of the difunctional amine compound (B31) are shown below.

### (Aliphatic Amine)

A difunctional amine compound such as ethylenediamine, hexamethylenediamine, nonamethylenediamine, undecanemethylenediamine, dodecamethylenediamine, metaxylylenediamine, 1,3-propanediamine, and putrescine.

### (Alicyclic Amine)

A difunctional amine compound such as a polyamine, e.g., isophoronediamine and cyclohexyldiamine.

### (Aromatic Amine)

A difunctional amine compound such as 4,4′-methylenebis(o-chloroaniline) (MOCA), 2,6-dichloro-p-phenylenediamine, 4,4′-methylenebis(2,3-dichloroaniline), 4,4′-methylenebis(2-ethyl-6-methylaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene glycol-di-p-aminobenzoate, 4,4′-diamino-3,3′,5,5′-tetraethyldiphenylmethane, 4,4′-diamino-3,3′-diisopropyl-5,5′-dimethyldiphenylmethane, 4,4′-diamino-3,3′-5,5′-tetraisopopyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 3,3′-diethyl-4,4′-diaminodiphenylmethane, m-xylylenediamine, N,N′-di-sec-butyl-p-phenylenediamine, m-phenylenediamine, p-xylylenediamine, p-phenylenediamine, 3,3′-methylenebis(methyl-6-aminobenzoate), 2-methylpropyl 2,4-diamino-4-chlorobenzoate, isopropyl 2,4-diamino-4-chlorobenzoate, isopropyl 2,4-diamino-4-chlorophenylacetate, di-(2-aminophenyl)thioethyl terephthalate, diphenylmethanediamine, tolylenediamine, and piperazine.

### (Production Method for Urethane Prepolymer (B12))

The urethane prepolymer (B12) is produced by reacting the above-mentioned difunctional isocyanate compound and (B21) a difunctional polyol compound and/or (B31) a difunctional amine compound. In the present invention, the urethane prepolymer (B12) must contain an unreacted isocyanate group. The production method for the (B12) urethane prepolymer having an isocyanate group may be any known method with no limitation, and for example, employable is a production method where the molar number (n5) of the isocyanate group in a difunctional isocyanate compound and the molar number (n6) of the active hydrogen-having group of the difunctional polyol compound (B21) and/or the difunctional amine compound (B31) fall within a range of 1<(n5)/(n6)≤2.3. In the case where two or more kinds of difunctional isocyanate compounds are used, the molar number (n5) of the isocyanate group is a molar number of the total isocyanate groups of the difunctional isocyanate compounds. In the case where two or more kinds of difunctional polyol compound (B21) and/or difunctional amine compound (B31) are used, the molar number (n6) of the active hydrogen-having group is a molar number of the total hydrogen atom-having groups of the difunctional polyol compound (B21) and/or the difunctional amine compound (B31). In the present invention where the active hydrogen is a primary amino group, the primary amino group is calculated as one mol. The reason is because, in reacting the second amino group (—NH) in the primary amino group, considerable energy is required (even in a primary amino group, the second —NH is difficult to react), and therefore in the present invention, even in using a difunctional active hydrogen-containing compound having a primary amino group, the primary amino group is calculated as one mol.

Though not specifically limited, the isocyanate equivalent of the urethane prepolymer (B12) (a value calculated by dividing the molecular weight of the urethane prepolymer (B12) by the number of the isocyanate groups in one molecule) is preferably 300 to 5000, more preferably 350 to 3000, even more preferably 400 to 2000. In the present invention, the urethane prepolymer (B12) is preferably a linear one produced from a difunctional isocyanate compound and the difunctional polyol compound (B21) and/or the difunctional amine compound(B31), and in that case, both the terminals are isocyanate groups, and the number of the isocyanate groups in one molecule is 2.

Regarding the isocyanate equivalent of the urethane prepolymer (B12), the isocyanate group that the urethane prepolymer (B12) has can be quantitatively determined by a back titration method mentioned below, according to JIS K 7301. First, the urethane prepolymer (B12) produced is dissolved in a dry solvent. Next, di-n-butylamine having a known concentration is added to the dry solvent in an amount obviously excessive over the amount of the isocyanate groups that the urethane prepolymer (B12) has to thereby react all the isocyanate groups of the urethane prepolymer (B12) and di-n-butylamine. Next, di-n-butylamine not consumed (not involved in the reaction) is titrated with an acid to determine the amount of the consumed di-n-butylamine. The amount of the consumed di-n-butylamine is the same as the amount of the isocyanate groups that the urethane prepolymer (B12) has, and therefore, the isocyanate equivalent can be calculated. For example, for a linear urethane prepolymer (B12) containing isocyanate groups, the number-average molecular weight of the urethane prepolymer (B12) is two times the isocyanate equivalent. The molecular weight of the urethane prepolymer (B12) easily matches the value measured by gel permeation chromatography (GPC). In the case where the urethane prepolymer (B12) and a difunctional isocyanate compound are used together, a mixture of the two may be measured according to the above-mentioned method.

Further, it is preferable that the isocyanate content ((I); molar concentration by mass (mol/kg)) in the urethane prepolymer (B12) and the urethane bond content ((U); molar concentration by mass (mol/kg)) in the urethane prepolymer (B12) satisfy 1≤(U)/(I)≤10. The range may apply to the case where the urethane prepolymer (B12) and a difunctional isocyanate compound are used together.

The isocyanate content ((I); molar concentration by mass (mol/kg)) is a value calculated by multiplying the reciprocal of the isocyanate equivalent by 1,000. For the urethane bond content in the urethane prepolymer (B12) ((U); molar concentration by mass (mol/kg), a theoretical value thereof can be determined according to the following method. Specifically when the content of the isocyanate groups before reaction existing in the difunctional isocyanate compound that constitutes the urethane prepolymer (B12) is referred to as a total isocyanate content ((al); molar concentration by mass (mol/kg)), the urethane bond content ((U); molar concentration by mass (mol/kg)) in the urethane prepolymer (B12) is a value calculated by subtracting the isocyanate content ((I); molar concentration by mass (mol/kg)) from the total isocyanate content ((al); molar concentration by mass (mol/kg)), ((U)=(al)−(I)).

In production of the urethane prepolymer (B12), as needed, the system may be heated or an urethanation catalyst can be added thereto. Any suitable urethanation catalyst may be used, and as specific examples thereof, the urethanation catalyst to be mentioned hereinunder can be used.

Most preferred examples of the component (B1) for use in the present invention are, from the viewpoint of the strength of the microballoons to be formed and reactivity control, an alicyclic isocyanate such as isophorone diisocyanate, 1,3-bis(isocyanatomethyl)cyclohexane, and (bicyclo[2.2.1]heptane-2,5(2,6)-diyl)bismethylene diisocyanate, an aromatic isocyanate such as 2,4-tolylene diisocyanate, 2,6-tolylene diisocyanate, 4,4′-diphenylmethane diisocyanate, and xylylene diisocyanate (o-, m-, p-), a polyfunctional isocyanate having a biuret structure, a uretdione structure or an isocyanurate structure, for which diisocyanates such as hexamethylene diisocyanate or tolylene diisocyanate are main materials, a polyfunctional isocyanate as an adduct with a tri- or higher polyol, and the urethane prepolymer (B12).

Among these, especially preferred are a polyfunctional isocyanate having a biuret structure, a uretdione structure or an isocyanurate structure, for which diisocyanates such as hexamethylene diisocyanate or tolylene diisocyanate are main materials, a polyfunctional isocyanate as an adduct with a tri- or higher polyol, and the urethane prepolymer (B12).

### <(B2) Polyol Compound Having at Least Two Hydroxy Groups>

The polyol compound (B2) for use in the present invention may be any one with no limitation, so far as it is a compound having at least two hydroxy groups in one molecule. The compound also includes the difunctional polyol compound (B21) for use in production of the urethane prepolymer (B12). The component (B2) is favorably used in hollow microballoons formed of a urethane(urea) resin. The component (B2) especially favorably used for the hollow microballoons of the present invention is a water-soluble polyol compound.

In the present invention, the water-soluble polyol compound is a compound at least partially soluble in water and having a high affinity in a hydrophilic phase than in a hydrophobic phase. For this, in general, one having a solubility at room temperature of at least 1 g/l in a hydrophilic solvent such as water can be selected. Preferably selected is a water-soluble compound having a solubility of 20 g/l or more in a hydrophilic solvent.

These water-soluble polyol compounds are polyfunctional alcohols having at least two hydroxy groups in the molecule, and specific examples thereof include difunctional polyols such as ethylene glycol, diethylene glycol, triethylene glycol, polyethylene glycol, propylene glycol, dipropylene glycol, tripropylene glycol, polypropylene glycol, neopentyl glycol, trimethylene glycol, 1,2-butanediol, 1,3-butanediol, 2,3-butanediol, 1,4-butanediol, 1,5-pentanediol, hexylene glycol, 1,6-hexanediol, and 2-butene-1,4-diol, trifunctional polyols such as glycerin, trimethylolethane, and trimethylolpropane, tetrafunctional polyols such as pentaerythritol, erythritol, diglycerol, diglycerin, and ditrimethylolpropane, pentafunctional polyols such as arabitol, hexafunctional polyols such as dulcitol, sorbitol, mannitol, dipentaerythritol, and triglycerol, heptafunctional polyols such as volemitol, nona-functional polyols such as isomaltose, maltitol, isomaltitol, and lactitol, and other water-soluble polymers such as cellulose compound (e.g., methyl cellulose, ethyl cellulose, hydroxyethyl cellulose, ethylhydroxyethyl cellulose, carboxymethyl cellulose, hydroxypropyl cellulose and saponified derivatives thereof), starch, dextrin, cyclodextrin, chitin, chitosan, polyvinyl alcohol, and polyglycerin.

### <(B3) Polyfunctional Amine Compound Having at Least Two Amino Groups>

The polyfunctional amine compound (B3) for use in the present invention may be any one with not limitation, so far as it has at least two amino groups in one molecule. This includes the difunctional amine (B31) used for producing the urethane prepolymer (B12). The component (B3) is favorably used in hollow microballoons formed of a urethane(urea) resin or an amide resin. The component (B3) especially favorably used in the hollow microballoons of the present invention is a water-soluble polyamine compound.

The preferred solubility of the water-soluble polyamine compound is the same as that of the above-mentioned water-soluble polyol compound. These water-soluble polyamine compounds are polyfunctional amines having at least two amino groups in the molecule, and specific examples thereof include ethylenediamine, propylenediamine, 1,4-diaminobutane, hexamethylenediamine, 1,8-diaminooctane, 1,10-diaminodecane, dipropylenetriamine, bishexamethylenetriamine, tris(2-aminoethyl)amine, piperazine, 2-methylpiperazine, isophoronediamine, diethylenetriamine, triethylenetetramine, tetraethylenepentamine, hydrazine, polyethyleneimines, polyoxyalkyleneamines, and polyethyleneimine.

### <(B4) Compound Having at Least Both a Hydroxy Group and an Amino Group>

The compound having at least both a hydroxy group and an amino group for use in the present invention may be any one with no limitation so far as it has at least one hydroxy group and at least one amino group in the molecule. The component (B4) is favorably used in hollow microballoons formed of a urethane(urea) resin. The component (B4) especially favorably usable herein is a water-soluble compound having both a hydroxy group and an amino group in the molecule.

The preferred solubility of the water-soluble compound having both a hydroxy group and an amino group in the molecule is the same as that of the above-mentioned water-soluble polyol compound. Specific examples of the water-soluble compound having both a hydroxy group and an amino group in the molecule include hydroxyamine, monoethanolamine, 3-amino-1-propanol, 2-amino-2-hydroxymethylpropane-1,3-diol, 2-hydroxyethylethylenediamine, 2-hydroxyethylpropylenediamine, N,N-di-2-hydroxyethylethylenediamine, N,N-di-2-hydroxypropylethylenediamine, N,N-di-2-hydroxypropylpropylenediamne, N-methylethanolamine, diethanolamine, N,N-di-2-hydroxyethylethylenediamine, N,N-di-2-hydroxypropylethylenediamine, and N,N-di-2-hydroxypropylpropylenediamine.

In the present invention, among the components (B2) to (B4), the component (B3) is preferred from the viewpoint of the intensity of the microballoons to be formed and the reaction speed in polymerization.

### <(B5) Melamine Formaldehyde Prepolymer Compound>

The melamine formaldehyde prepolymer compound (B5) is a melamine-formaldehyde precondensation product of melamine and formaldehyde, and can be produced according to an ordinary method. Examples of the melamine-formaldehyde precondensation product of melamine and formaldehyde include methylolmelamine. As the melamine formaldehyde prepolymer compound, commercial products can be appropriately used. For example, the commercial products include Beckamine APM, Beckamine M-3, Beckamine M-3(60), Beckamine MA-S, Beckamine J-101, Beckamine J-1 01LF (by DIC Corporation), Nikaresin S-176, Nikaresin S-260 (by Nippon Carbide Industries Co., Inc.), and Mirbane Resin SM-800 (by Showa Denko K.K.).

The component (B5) is favorably used in hollow microballoons formed of a melamine resin.

### <(B6) Urea Formaldehyde Prepolymer Compound>

The urea formaldehyde prepolymer compound (B6) is a urea-formaldehyde precondensation product of urea and formaldehyde, and can be produced according to an ordinary method. Examples of the urea-formaldehyde precondensation product of urea and formaldehyde include methylolurea. As the urea formaldehyde prepolymer compound, commercial products can be appropriately used. For example, the commercial products include 8HSP (by Showa Denko K.K.).

The component (B6) is favorably used in hollow microballoons formed of a urea resin.

### <(B7) Polyfunctional Carboxylic Acid Compound Having at Least Two Carboxy Groups>

The polyfunctional carboxylic acid compound (B7) is preferably a dicarboxylic acid compound, and the dicarboxylic acid compound includes succinic acid, adipic acid, sebacic acid, dodecenylsuccinic acid, azelaic acid, sebacic acid, dodecanedicarboxylic acid, octadecanedicarboxylic acid, dodecenylsuccinic acid, pentadecenylsuccinic acid, octadecenylsuccinic acid, maleic acid, fumaric acid, and other alkenylenedicarboxylic acids, and decylsuccinic acid, dodecylsuccinic acid, octadecylsuccinic acid, phthalic acid, isophthalic acid, terephthalic acid, and naphthalenedicarboxylic acid.

The component also includes a dicarboxylic acid dihalide. Specific examples thereof include aliphatic dicarboxylic acid dihalides, alicyclic dicarboxylic acid dihalides, and aromatic dicarboxylic acid dihalides.

Examples of aliphatic dicarboxylic acid dihalides include oxalic acid dichloride, malonic acid dichloride, succinic acid dichloride, fumaric acid dichloride, glutaric acid dichloride, adipic acid dichloride, muconic acid dichloride, sebacic acid dichloride, nonanoic acid dichloride, undecanoic acid dichloride, oxalic acid dibromide, malonic acid dibromide, succinic acid dibromide, and fumaric acid dibromide.

Examples of alicyclic dicarboxylic acid dihalides include 1,2-cyclopropanedicarboxylic acid dichloride, 1,3-cyclobutanedicarboxylic acid dichloride, 1,3-cyclopentanedicarboxylic acid dichloride, 1,3-cyclohexanedicarboxylic acid dichloride, 1,4-cyclohexanedicarboxylic acid dichloride, 1,3-cyclopentanedicarboxylic acid dichloride, 1,2-cyclopropanedicarboxylic acid dibromide, and 1,3-cyclobutanedicarboxylic acid dibromide.

Examples of aromatic dicarboxylic acid dihalides include phthalic acid dichloride, isophthalic acid dichloride, terephthalic acid dichloride, 1,4-naphthalenedicarboxylic acid dichloride, 1,5-(9-oxofluorene)dicarboxylic acid dichloride, 1,4-anthracenedicarboxylic acid dichloride, 1,4-anthracenedicarboxylic acid dichloride, 2,5-biphenyldicarboxylic acid dichloride, 1,5-biphenylenedicarboxylic acid dichloride, 4,4′-biphenyldicarbonyl dichloride, 4,4′-methylene-dibenzoic acid dichloride, 4,4′-isopropylidene-dibenzoic acid dichloride, 4,4′-bibenzyldicarboxylic acid dichloride, 4,4′-stilbenedicarboxylic dichloride, 4,4′-tolandicarboxylic acid dichloride, 4,4′-carbonyldibenzoic acid dichloride, 4,4′-oxydibenzoic acid dichloride, 4,4′-sulfonyldibenzoic acid dichloride, 4,4′-dithiodibenzoic acid dichloride, p-phenylenediacetic acid dichloride, 3,3′-p-phenylenedipropionic acid dichloride, phthalic acid dibromide, isophthalic acid dibromide, and terephthalic acid dibromide.

In the present invention, preferred examples of the component (B7) are dicarboxylic acid dihalides, from the viewpoint of polymerization speed.

The resin to form the hollow microballoons of the present invention is produced by polymerization of a polymerizable composition containing the component (A) and the component (B), as mentioned above. The polymerizable composition may contain any other component than the component (A) and the component (B), but is preferably composed of the component (A) and the component (B) alone.

### <Production Method for Hollow Microballoons>

Any known method is employable with no limitation for the production method for the hollow microballoons of the present invention. For example, employable is a method of preparing microballoons according to a known method using emulsions by an aqueous phase and an oily phase, such as interfacial polymerization, coacervation or in-situ polymerization, followed by removing the liquid from the inside to produce hollow microballoons.

The hollow microballoons of the present invention are preferably formed of at least one resin selected from the group consisting of a urethane(urea) resin, a melamine resin, a urea resin and an amide resin. The hollow microballoons formed of such a resin can express not only excellent properties but also excellent polishing properties in use thereof for CMP polishing pads.

Specifically the hollow microballoons of the present invention can be produced, for example, according to the following methods, to which, however, the present invention is not limited. The polyrotaxane monomer (A) varies whether it is hydrophilic or oleophilic, depending on the kind and the introduction amount of the selected cyclic molecule and the side chains, and therefore, after the oleophilicity of the polyrotaxane monomer (A) used has been confirmed, it may be dissolved in an aqueous phase or an oily phase in use thereof.

<Case where the Hollow Microballoons are Formed of a Urethan(Urea) Resin or an Amide Resin>

In the case where the hollow microballoons are formed of a urethan(urea) resin or an amide resin, these may be formed by interfacial polymerization. In the case of interfacial polymerization, after an oil-in-water (O/W) emulsion (hereinafter this may be referred to as O/W emulsion), or a water-in-oil (W/O) emulsion (hereinafter this may be referred to as W/O emulsion) has been prepared, this may be polymerized at the interface to produce microballoons. In the present invention, any of an O/W emulsion or a W/O emulsion is selectable, but an O/W emulsion is preferred since interfacial polymerization of such an O/W emulsion can efficiently produce hollow microballoons. Hereinunder an interfacial polymerization of an O/W emulsion is exemplified. Except “case of an amide resin”, the following is an exemplification for a urethane(urea) resin.

The polymerization method of an O/W emulsion is briefly divided into the following, a first step: a step of preparing (a) an oily phase at least containing the component (B1) (in the case of an amide resin, the component (B7)) and an organic solvent (hereinafter also referred to as component (a)), a second step: a step of preparing (b) an aqueous phase containing an emulsifier (hereinafter also referred to as component (b)), a third step: a step of mixing and stirring the component (a) and the component (b) to prepare an O/W emulsion in which the aqueous phase is a continuous phase and the oily phase is a disperse phase, a fourth step: a step of adding a hydrophilic compound selected from the components (B2) to (B4) (in the case of an amide resin, the components (B3) to (B4) (the component (B4) in the “case of an amide resin” is limited to only the component (B4) having at least two amino groups—the same shall apply hereinunder)) to the O/W emulsion to promote polymerization on the O/W emulsion interface to form a resin film to give microballoons, thereby producing a microballoon dispersion where the microballoons are dispersed, a fifth step: a step of separating the microballoons from the microballoon dispersion, and a sixth step: a step of removing the organic solvent solution from inside of the microballoons. Here, in the case where the polyrotaxane monomer (A) in the present invention is oleophilic, the polyrotaxane monomer (A) may be uniformly dissolved in the component (a) in the first step, and in the case where the polyrotaxane monomer (A) is hydrophilic, the polyrotaxane monomer (A) may be added to the O/W emulsion along with the hydrophilic compound selected from the components (B2) to (B4) (in the case of an amide resin, the components (B3) and (B4)) in the fourth step 4. In that manner, the polyrotaxane monomer (A) can react with the component (B1) (in the case of an amide resin, the component (B7)).

### First Step:

The first step is a step of preparing the (a) oily phase at least containing the component (B1) (in the case of an amide resin, the component (B7)) and an organic solvent which is to be a disperse phase in the O/W emulsion.

The step is a step of dissolving the component (B1) (in the case of an amide resin, the component (B7)) in an organic solvent to be mentioned below to prepare an oily phase, and the component may be dissolved in a known method to prepare a uniform solution. In the case where the polyrotaxane monomer (A) is oleophilic, the component (A) may be dissolved in a solution of the above-mentioned oily phase to give a uniform solution of the component (a).

In the case where the hollow microballoons are formed of a urethane(urea) resin, a preferred amount to be used of the component (B1) is 0.1 to 50 parts by mass relative to 100 part by mass of the organic solvent, more preferably 0.5 to 20 parts by mass, even more preferably 1 to 10 parts by mass. In the case where the molar number of all the active hydrogen group-containing compounds of the component (A) and the components (B2) to (B4) is referred to as (n2), relative to the molar number (n1) of the isocyanate groups that the component (B1) has, n1 and n2 preferably fall within a range of 0.5<(n1)/(n2)<2.

In the case where the hollow microballoons are formed of an amide resin, a preferred amount to be used of the component (B7) is 0.1 to 50 parts by mass relative to 100 part by mass of the organic solvent, more preferably 0.5 to 20 parts by mass, even more preferably 1 to 10 parts by mass. In the case where the molar number of all the active hydrogen group-containing compounds of the component (A) and the components (B3) to (B4) is referred to as (n4), relative to the molar number (n3) of the carboxylic acid groups that the component (B7) has, n3 and n4 preferably fall within a range of 0.5<(n3)/(n4)<2.

A catalyst to be mentioned below may be added to the component (a) for the purpose of promoting the interfacial polymerization reaction.

### Second Step:

The second step is a step of preparing the (b) aqueous phase containing an emulsifier and water, which is to be a continuous phase in the O/W emulsion.

The step is a step of dissolving an emulsifier to be mentioned below in water to prepare an aqueous phase, and an emulsifier may be dissolved in a known method to give a uniform solution.

In the present invention, the amount to be used of the emulsifier is 0.01 to 20 parts by mass relative to 100 parts by mass of water, preferably 0.1 to 10 parts by mass. Within the range, aggregation of the liquid drops of the disperse phase in the O/W emulsion can be prevented, and microballoons having a uniform average particle size are easy to produce.

A catalyst to be mentioned below may be added to the component (b) for promoting the interfacial polymerization reaction.

### Third Step:

The third step is a step of mixing and stirring the component (a) prepared in the first step and the component (b) prepared in the second step to prepare an O/W emulsion in which the component (a) is a disperse phase and the component (b) is a continuous phase.

In the present invention, the method of mixing and stirring the component (a) and the component (b) to give an O/W emulsion may be a method of mixing and stirring them in consideration of the particle size of the microballoons to be produced and according to an appropriate known method.

In particular, a method of preparing an O/W emulsion is preferably employed, in which the component (a) and the component (b) are, after having been mixed, dispersed by stirring using a known dispersing machine of a high-speed shear mode, a friction mode, a high-pressure jet mode or an ultrasonic wave mode. Among these, a high-speed shear mode is preferred. In the case where a high-speed shear mode dispersing machine is used, the rotation number is preferably 500 to 20,000 rpm, more preferably 1,000 to 10,000 rpm. The dispersion time is preferably 0.1 to 60 minutes, more preferably 0.5 to 30 minutes. The dispersion temperature is preferably 10 to 40° C.

In the present invention, the ratio by weight of the component (a) to the component (b) is preferably such that the component (a) is 1 to 100 parts by mass relative to 100 parts by mass of the component (b), more preferably 2 to 90 parts by mass, even more preferably 5 to 50 parts by mass. Within the range, a good emulsion can be produced.

### Fourth Step:

The fourth step is a step of adding at least one compound selected from the components (B2) to (B4) (in the case of an amide resin, the components (B3) to (B4)) to the O/W emulsion for polymerization on the O/W emulsion interface to form a resin film to give microballoons, thereby producing a microballoon dispersion where the microballoons are dispersed. In the case where the polyrotaxane monomer (A) is hydrophilic, it may be added to the O/W emulsion along with at least one compound selected from the components (B2) to (B4) (in the case of an amide resin, the components (B3) to (B4)) in the fourth step.

In the case where the components (B2) to (B4) (in the case of an amide resin, the components (B3) to (B4)) and the component (A) are added to the O/W emulsion, they may be directly added thereto or may be previously dissolved in water prior to addition.

In the case where the components are dissolved in water, preferably the amount of water to be used is in a range of 50 to 10,000 parts by mass relative to 100 parts by mass of the total amount of the components (B2) to (B4) (in the case of an amide resin, the components (B3) to (B4)) and the component (A),

The reaction temperature is not specifically limited so far as the O/W emulsion is not broken at the temperature, and preferably the reaction is carried out within a range of 5 to 70° C. The reaction time is not also specifically limited, so far as the W/O emulsion can be formed within the time, and is generally selected from a range of 0.5 to 24 hours.

### Fifth Step

The fifth step is a step of separating the microballoons from the microballoon dispersion. The method of separating the microballoons from the microballoon dispersion is not specifically limited, and can be selected from ordinary separation methods. For example, filtration or centrifugal separation is employed.

### Sixth Step

The sixth step is step of removing the oily phase from inside of the microballoons obtained in the fifth step to give hollow microballoons. The method for removing the oily phase from the microballoons is not specifically limited, and can be selected from ordinary separation methods. For example, a circulation air drier, a spray drier, a fluidized bed drier, or a vacuum drier can be used. The temperature at drying is preferably 40 to 250° C., more preferably 50 to 200° C.

<Case where the Hollow Microballoons are Formed of a Melamine Resin or a Urea Resin>

Also in the case where the hollow microballoons are formed of a melamine resin or a urea resin, these may be formed by interfacial polymerization or in-situ polymerization after an O/W emulsion has been prepared. Hereinunder specific examples are shown, but the production method in the present invention is not limited thereto.

The polymerization method of an O/W emulsion for the hollow microballoons formed of a melamine resin or a urea resin is briefly divided into the following, a first step: a step of preparing (c) an oily phase containing an organic solvent (hereinafter also referred to as component (c)), a second step: a step of preparing (d) an aqueous phase containing an emulsifier (hereinafter also referred to as component (d)), a third step: a step of mixing and stirring the component (c) and the component (d) to prepare an O/W emulsion in which the aqueous phase is a continuous phase and the oily phase is a disperse phase, a fourth step: a step of adding the component (B5) or the component (B6) to the O/W emulsion to promote polymerization on the O/W emulsion interface to form a resin film, thereby producing a microballoon dispersion where microballoons are dispersed, a fifth step: a step of separating the microballoons from the microballoon dispersion, and a sixth step: a step of removing the organic solvent solution from inside of the microballoons. Here, in the case where the polyrotaxane monomer (A) in the present invention is oleophilic, it may be uniformly dissolved in the oily phase in the first step, and in the case where the polyrotaxane monomer (A) is hydrophilic, it may be added along with the component (B5) or the component (B6). In that manner, the polyrotaxane monomer (A) can be taken in the resin that constitutes the microballoons along with the component (B5) or the component (B6).

### First Step:

The first step is a step of preparing the (c) oily phase containing an organic solvent which is to be a disperse phase in the O/W emulsion.

In this step where the polyrotaxane monomer (A) is oleophilic, the component (A) may be dissolved in the above-mentioned organic solvent to prepare a uniform oily phase.

On the other hand, in the case where the polyrotaxane monomer (A) is hydrophilic, the component (A) is not dissolved in the organic solvent, and therefore the organic solvent may be merely an oily phase.

### Second Step:

The second step is a step of preparing the (d) aqueous phase containing an emulsifier and water, which is to be a continuous phase in the O/W emulsion and controlling pH.

The step includes a step of dissolving an emulsifier to be mentioned below in water followed by pH control. For pH control, a known method may be used.

In the present invention, the amount to be used of the emulsifier is 0.01 to 20 parts by mass relative to 100 parts by mass of water, preferably 0.1 to 10 parts by mass. Within the range, aggregation of the liquid drops of the disperse phase in the O/W emulsion can be prevented, and microballoons having a uniform average particle size are easy to produce.

Preferably the pH controlled to be less than 7, more preferably within a range of 3.5 to 6.5, most preferably 4.0 to 5.5. Falling within the pH range, polymerization of the component (B5) or the component (B6) to be mentioned below can be promoted.

### Third Step:

The third step is a step of mixing and stirring the component (c) prepared in the first step and the component (d) prepared in the second step to prepare an O/W emulsion in which the component (c) is a disperse phase and the component (d) is a continuous phase.

In the present invention, the method of mixing and stirring the component (c) and the component (d) to give an O/W emulsion may be a method of mixing and stirring them in consideration of the particle size of the microballoons to be produced and according to an appropriate known method. In addition, in the step of preparing the O/W emulsion, the temperature and the pH can be controlled.

In particular, a method of preparing an O/W emulsion is preferably employed, in which the component (c) and the component (d) are, after having been mixed, dispersed by stirring using a known dispersing machine of a high-speed shear mode, a friction mode, a high-pressure jet mode or an ultrasonic wave mode. Among these, a high-speed shear mode is preferred. In the case where a high-speed shear mode dispersing machine is used, the rotation number is preferably 500 to 20,000 rpm, more preferably 1,000 to 10,000 rpm. The dispersion time is preferably 0.1 to 60 minutes, more preferably 0.5 to 30 minutes. The dispersion temperature is preferably 20 to 90° C.

In the present invention, the ratio by weight of the component (c) to the component (d) is preferably such that the component (c) is 1 to 100 parts by mass relative to 100 parts by mass of the component (d), more preferably 2 to 90 parts by mass, even more preferably 5 to 50 parts by mass. Within the range, a good emulsion can be produced.

### Fourth Step:

The fourth step is a step of adding the component (B5) or the component (B6) to the O/W emulsion for polymerization on the O/W emulsion interface to form a resin film to give microballoons, thereby producing a microballoon dispersion where the microballoons are dispersed.

The amount to be used of the component (B5) or the component (B6) is not specifically limited, but for forming good microballoons, the amount is preferably 0.5 to 50 parts by mass relative to 100 parts by mass of the organic solvent used in the first step, more preferably 1 to 20 parts by mass.

In the case where the polyrotaxane (A) is hydrophilic, it may be added to the O/W emulsion along with the component (B5) or the component (B6) in the fourth step.

In the case where the components (B5) or the component (B6), and the component (A) are added to the O/W emulsion, they may be directly added thereto or may be previously dissolved in water prior to addition.

In the case where the components are dissolved in water, preferably the amount of water to be used is in a range of 50 to 10,000 parts by mass relative to 100 parts by mass of the total amount of the components (B5) or the component (B6), and the component (A).

The pH of the aqueous phase of a continuous phase may be controlled in the second step, or after the component (B5) or the component (B6) is added in the fourth step, it may be controlled. The pH of the aqueous phase of a continuous phase is preferably at least less than 7. Regarding the preferred reaction temperature, the reaction is carried out preferably in a range of 40 to 90° C. The reaction time is preferably 1 to 48 hours.

### Fifth Step, Sixth Step

The fifth step and the sixth step are the same as in the case where the hollow microballoons are formed of a urethane(urea) resin (or polyamide resin).

### <Preferred Formulation Ratio>

The content of the polyrotaxane monomer (A) in the polymerizable composition for use in producing the resin to constitute the hollow microballoons of the present invention is preferably 1 to 50 parts by mass relative to 100 parts by mass of the total of the polyrotaxane monomer (A) and the polymerizable monomer (B). When the composition contains the polyrotaxane monomer (A) in that ratio, it can express excellent durability and excellent properties. In the case where the hollow microballoons are used for a CMP polishing pad, the pad can express not only excellent durability but also excellent polishing characteristics.

Especially more preferably the component (A) is 2 to 40 parts by mass relative to 100 parts by mass of the total of the polyrotaxane monomer (A) and the polymerizable monomer (B), and even more preferably the component (A) is 3 to 30 parts by mass.

The content of the component (A) can be determined by analysis such as solid NMR of the polymerized resin, but in general, it is determined from the amount thereof used. In the case of an O/W emulsion, it is considered that all the amount used of the component (A) and the component (B) contained in the oily phase can be contained in the resin constituting the microballoons. On the other hand, it is also considered that all the amount used of the component (A) and the component (B) added to an aqueous phase can be contained in the resin constituting the microballoons, so far as the amount used falls within the above-mentioned preferred range. The components whose amount added falls without the preferred range, that is, the component (B) in the fourth step and the component (A) added in an amount falling outside the preferred range can be determined by identifying the component (B) and the component (A) having remained in the form not involved in polymerization by analysis of the aqueous phase after the reaction. Taking these into consideration, it is possible to define the amount of the monomer involved in formation of microballoons.

Namely in other words, the content of the component (A) in the resin constituting the hollow microballoons of the present invention is preferably 1 to 50 parts by mass relative to 100 parts by mass of the total content of the component (A) and the component (B), more preferably 2 to 40 parts by mass, even more preferably 3 to 30 parts by mass.

Falling within the above-mentioned range, microballoons can be efficiently produced in emulsion.

The components used in the present invention are described below.

### <Emulsifier>

In the present invention, as the emulsifier for the component (b) or the component (b), usable is a dispersant, a surfactant or a combination of these.

Examples of the dispersant include polyvinyl alcohol and modified derivatives thereof (for example, anion-modified polyvinyl alcohol), cellulosic compounds (for example, methyl cellulose, ethyl cellulose, hydroxyethyl cellulose, ethylhydroxyethyl cellulose, carboxymethyl cellulose, hydroxypropyl cellulose and saponified derivatives thereof), polyacrylic acid amide and derivatives thereof, ethylene-vinyl acetate copolymer, styrene-maleic anhydride copolymer, ethylene-maleic anhydride copolymer, isobutylene-maleic anhydride copolymer, polyvinyl pyrrolidone, ethylene-acrylic acid copolymer, vinyl acetate-acrylic acid copolymer, sodium polyacrylate, potassium polyacrylate, ammonium polyacrylate, partially neutralized derivatives of polyacrylic acid, sodium acrylate-acrylate copolymer, carboxymethyl cellulose, casein, gelatin, dextrin, chitin, chitosan, starch derivatives, gum arabic and sodium alginate.

Preferably, these dispersants do not react with or extremely hardly react with the polymerizable composition used in the present invention. Therefore, it is desirable that those having a reactive amino group in the molecular chain, such as gelatin, are previously processed for treatment to lose reactivity.

The surfactant includes an anionic surfactant, a cationic surfactant, an ampholytic surfactant, and a nonionic surfactant. Two or more kinds of surfactants can be sued as combined.

The anionic surfactant includes a carboxylic acid or a salt thereof, a sulfate ester salt, a salt of a carboxymethylated substance, a sulfonic acid salt and a phosphate ester salt.

The carboxylic acid or a salt thereof includes a saturated or unsaturated fatty acid having 8 to 22 carbon atoms, or a salt thereof, and specific examples include capric acid, lauric acid, myristic acid, palmitic acid, stearic acid, arachidic acid, behenic acid, oleic acid, linolic acid, ricinoleic acid, and a mixture of higher fatty acids obtained by saponifying palm oil, palm kernel oil, rice bran oil or beef tallow. The salt includes salts of the above with sodium, potassium, ammonium or alkanolamine.

The sulfate ester salt includes a higher alcohol sulfate ester salt (a sulfate ester salt of an aliphatic alcohol having 8 to 18 carbon atoms), a higher alkyl ether sulfate ester salt (a sulfate ester salt of an ethylene oxide adduct of an aliphatic alcohol having 8 to 18 carbon atoms), a sulfated oil (an unsaturated oil or fat or an unsaturated wax is directly sulfated and neutralized), a sulfated fatty acid ester (a lower alcohol ester of an unsaturated fatty acid is sulfated and neutralized), and a sulfated olefin (an olefin having 12 to 18 carbon atoms is sulfated and neutralized). The salt includes a sodium salt, a potassium salt, an ammonium salt and an alkanolamine salt.

Specific examples of the higher alcohol sulfate ester salt include an octyl alcohol sulfate ester salt, a decyl alcohol sulfate ester salt, a lauryl alcohol sulfate ester salt, a stearyl alcohol sulfate ester salt, and a sulfate ester salt of an alcohol synthesized in an oxo method (Oxocol 900, tridecanol: by Kyowa Hakko Co., Ltd.).

Specific examples of the higher alkyl ether sulfate ester salt include a lauryl alcohol ethylene oxide (2 mols) adduct sulfate ester salt, and an octyl alcohol ethylene oxide (3 mols) adduct sulfate ester salt.

Specific examples of the sulfated oil include sodium, potassium, ammonium or alkanolamine salts of sulfated castor oil, peanut oil, olive oil, rapeseed oil, beef tallow or mutton tallow.

Specific examples of the sulfated fatty acid ester include sodium, potassium, ammonium or alkanolamine salts of sulfated butyl oleate or butyl ricinoleate.

The salt of a carboxymethylated compound includes a salt of a carboxymethylated aliphatic alcohol having 8 to 18 carbon atoms, and a salt of a carboxymethylated ethylene oxide adduct of an aliphatic alcohol having 8 to 16 carbon atoms.

Specific examples of the salt of a carboxymethylated aliphatic alcohol include an octyl alcohol carboxymethylated sodium salt, a decyl alcohol carboxymethylated sodium salt, a lauryl alcohol carboxymethylated sodium salt, and a tridecanol carboxymethylated sodium salt.

Specific example of the aliphatic alcohol ethylene oxide carboxymethylated salt include an octyl alcohol ethylene oxide (3 mols) adduct carboxymethylated sodium salt, a lauryl alcohol ethylene oxide (4 mols) adduct carboxymethylated sodium salt, and a tridecanol ethylene oxide (5 mols) adduct carboxymethylated sodium salt.

The sulfonate salt includes an alkylbenzene sulfonate salt, an alkylnaphthalene sulfonate salt, a sulfosuccinic acid diester-type salt, an α-olefin sulfonate salt, an Igepon T-type salt, and other aromatic ring-containing compound sulfonate salts.

Specific examples of the alkylbenzene sulfonate salt include sodium dodecylbenzene sulfonate.

Specific examples of the alkylnaphthalene sulfonate salt include dodecylnapthalene sulfonate sodium salt.

Specific examples of the sulfosuccinic acid diester-type salt include sulfosuccinic acid di-2-ethylhexyl ester sodium salt.

The sulfonic acid salt of an aromatic ring-containing compound includes an alkylated diphenyl ether mono- or di-sulfonate salt, and a styrenated phenolsulfonate salt.

The phosphate ester salt includes a higher alcohol phosphate ester salt, and a higher alcohol ethylene oxide adduct phosphate ester salt.

Specific examples of the higher alcohol phosphate ester salt include lauryl alcohol phosphoric acid monoester disodium salt, and lauryl alcohol phosphoric acid diester sodium salt.

Specific examples of the higher alcohol ethylene oxide adduct phosphate ester salt include oleyl alcohol ethylene oxide (5 mols) adduct phosphoric acid monoester disodium salt.

The cationic surfactant includes a quaternary ammonium salt-type surfactant and an amine salt-type surfactant.

The quaternary ammonium salt-type surfactant includes reaction products of a tertiary amine and a quaternizing agent (e.g., alkylating agent such as methyl chloride, methyl bromide, ethyl chloride, benzyl chloride, dimethyl sulfate, and ethylene oxide), such as lauryltrimethylammonium chloride, didecyldimethylammonium chloride, dioctyldimethylammonium bromide, stearyltrimethylammonium bromide, lauryldimethylbenzylammonium chloride (benzalkonium chloride), cetylpyridinium chloride, polyoxyethylene trimethylammonium chloride, and stearamidoethyldiethylmethylammonium methosulfate.

The amine-type surfactant is obtained by neutralizing a mono- to triamine with an inorganic acid (e.g., hydrochloric acid, nitric acid, sulfuric acid, hydroiodic acid) or an organic acid (e.g., acetic acid, formic acid, oxalic acid, lactic acid, gluconic acid, adipic acid, or alkylphosphoric acid). Examples of the primary amine salt-type surfactant includes an inorganic acid salt or an organic acid salt of an aliphatic higher amine (higher amine such as laurylamine, stearylamine, cetylamine, hardened beef tallow amine, or rosin amine), and a higher fatty acid (e.g., stearic acid or oleic acid) salt of a lower amine.

Examples of the secondary amine-type surfactant include an inorganic acid salt or an organic acid salt of an aliphatic amine ethylene oxide adduct.

Examples of the tertiary amine-type surfactant include an inorganic acid salt or an organic acid salt of an aliphatic amine (e.g., triethylamine, ethyldimethylamine, N,N,N′,N′-tetramethylethylenediamine), an aliphatic amine ethylene oxide adduct, an alicyclic amine (e.g., N-methylpyrrolidine, N-methylpiperidine, N-methylhexamethyleneimine, N-methylmorpholine, 1,8-diazabicyclo(5,4,0)-7-undecene), or a nitrogen-containing heterocyclic aromatic amine (e.g., 4-dimethylaminopyridine, N-methylimidazole, 4,4′-dipyridyl), and an inorganic acid salt or an organic acid salt of a tertiary amine such as triethanolamine monostearate, and stearamidoethyldiethylmethylethanolamine.

The ampholytic surfactant includes a carboxylate salt-type ampholytic surfactant, a sulfate ester salt-type ampholytic surfactant, a sulfonate salt-type ampholytic surfactant, and a phosphate ester salt-type ampholytic surfactant. The carboxylate salt-type ampholytic surfactant includes an amino acid-type ampholytic surfactant and a betaine-type ampholytic surfactant.

The carboxylate salt-type ampholytic surfactant includes an amino acid-type ampholytic surfactant, a betaine-type ampholytic surfactant, and an imidazoline-type ampholytic surfactant. Among these, the amino acid-type ampholytic surfactant is an ampholytic surfactant having an amino group and a carboxy group in the molecule, and specifically examples thereof include an alkylaminopropionate-type ampholytic surfactant (e.g., sodium stearylaminopropionate, sodium laurylaminopropionate), and an alkylaminoacetate-type ampholytic surfactant (e.g., sodium laurylaminoacetate).

The betaine-type ampholytic is an ampholytic surfactant having a quaternary ammonium salt-type cationic moiety and a carboxylate-type anionic moiety in the molecule, and examples thereof include an alkyldimethylbetaine (e.g., stearyl dimethylaminoacetate betaine, lauryl dimethylaminoacetate betaine), an amidobetaine (e.g., coconut oil fatty acid amide propylbetaine), and an alkyldihydroxyalkyl betaine (e.g., lauryldihydroxyethyl betaine).

Examples of the imidazoline-type ampholytic surfactant include 2-undecyl-N-carboxymethyl-N-hydroxyethylimidazolinium betaine.

Examples of other ampholytic surfactants include glycine-type ampholytic surfactants such as sodium lauroylglycine, sodium lauryldiaminoethylglycine, lauryldiaminoethylglycine hydrochloride, and dioctyldiaminoethylglycine hydrochloride, and sulfobetaine-type ampholytic surfactants such as pentadecylsulfotaurine.

The nonionic surfactant includes an alkylene oxide adduct-type nonionic surfactant and a polyalcohol-type nonionic surfactant.

The alkylene oxide adduct-type nonionic surfactant is obtained by reacting a polyalkylene glycol, which is obtained by directly adding an alkylene oxide to a higher alcohol, a higher fatty acid or an alkylamine, or by adding an alkylene oxide to a glycol, with a higher fatty acid, or is obtained by adding an alkylene oxide to an esterified product, which is obtained by reacting a higher fatty acid with a polyalcohol, or by adding an alkylene oxide to a higher fatty acid amide.

Examples of the alkylene oxide include ethylene oxide, propylene oxide and butylene oxide.

Specific examples of the alkylene oxide adduct-type nonionic surfactant include an oxyalkylene alkyl ether (e.g., octyl alcohol ethylene oxide adduct, lauryl alcohol ethylene oxide adduct, stearyl alcohol ethylene oxide adduct, oleyl alcohol ethylene oxide adduct, lauryl alcohol ethylene oxide propylene oxide block adduct), a polyoxyalkylene higher fatty acid ester (e.g., stearyl acid ethylene oxide adduct, lauryl acid ethylene oxide adduct), a polyoxyalkylene polyalcohol higher fatty acid ester (e.g., polyethylene glycol lauryl acid diester, polyethylene glycol oleic acid diester, polyethylene glycol stearic acid diester), a polyoxyalkylene alkyl phenyl ether (e.g., nonylphenol ethylene oxide adduct, nonylphenol ethylene oxide propylene oxide block adduct, octylphenol ethylene oxide adduct, bisphenol A ethylene oxide adduct, dinonylphenol ethylene oxide adduct, styrenated phenol ethylene oxide adduct), a polyoxyalkylene alkylamino ether (e.g., laurylamine ethylene oxide adduct, stearylamine ethylene oxide adduct), and a polyoxyalkylene alkylalkanolamide (e.g., hydroxyethylauric acid amide ethylene oxide adduct, hydroxypropyloleic acid amide ethylene oxide adduct, dihydroxyethylauric acid amide ethylene oxide adduct).

The polyalcohol-type nonionic surfactant includes a polyalcohol fatty acid ester, a polyalcohol fatty acid ester alkylene oxide adduct, a polyalcohol alkyl ether, and a polyalcohol alkyl ether alkylene oxide adduct.

Specific examples of the polyalcohol fatty acid ester include pentaerythritol monolaurate, pentaerythritol monooleate, sorbitan monolaurate, sorbitan monostearate, sorbitan monolaurate, sorbitan dilaurate, sorbitan dioleate, and sucrose monostearate.

Specific examples of the polyalcohol fatty acid ester alkylene oxide adduct include ethylene glycol monooleate ethylene oxide adduct, ethylene glycol monostearate ethylene oxide adduct, trimethylolpropane monostearate ethylene oxide propylene oxide random adduct, sorbitan monolaurate ethylene oxide adduct, sorbitan monostearate ethylene oxide adduct, sorbitan distearate ethylene oxide adduct, and sorbitan dilaurate ethylene oxide propylene oxide random adduct.

Specific examples of the polyalcohol alkyl ether include pentaerythritol monobutyl ether, pentaerythritol monolauryl ether, sorbitan monomethyl ether, sorbitan monostearyl ether, methyl glycoside, and lauryl glycoside.

Specific examples of the polyalcohol alkyl ether alkylene oxide adduct include sorbitan monostearyl ether ethylene oxide adduct, methyl glycoside ethylene oxide propylene oxide random adduct, lauryl glycoside ethylene oxide adduct, and stearyl glycoside ethylene oxide propylene oxide random adduct.

Among these, the emulsifier for use in the present invention is preferably selected from a dispersant and a nonionic surfactant, and specific examples of more preferred emulsifiers are mentioned below. In the case where the hollow microballoons of the present invention are formed of a urethane(urea) resin, preferred is polyvinyl alcohol or an anion-modified polyvinyl alcohol; and in the case where the hollow microballoons are formed of an amide resin, preferred is a sodium acrylate-acrylate copolymer. By selecting these, a stable emulsion can be formed.

In the case where the hollow microballoons are formed of a melamine resin or a urea resin, the emulsifier is preferably a styrene-maleic anhydride copolymer, and ethylene-maleic anhydride copolymer or an isobutylene-maleic anhydride copolymer. By neutralizing these with an alkaline compound such as sodium hydroxide, a high-density anionic polymer is produced, and this can promote polymerization of the component (B5) or the component (B6).

### <Organic Solvent>

In the present invention, the organic solvent used for the component (a) or the component (c) is not specifically limited so far as it can dissolve the component (B1), the component (B7) or the oleophilic component (A), and examples thereof include hydrocarbons, halides and ketones

Above all, preferred are those having a boiling point of 200° C. or lower, for removing the organic solvent from the inside of microballoons to give hollow microballoons, and more preferred are those having a boiling point of 150° C. or lower. Examples thereof are listed below.

### (Hydrocarbons)

Mentioned are aliphatic hydrocarbon having 6 to 11 carbon atoms, such as n-hexane, n-heptane and n-octane, an aromatic hydrocarbon such as benzene, toluene and xylene, and an alicyclic hydrocarbon such as cyclohexane, cyclopentane and methylcyclohexane.

### (Halides)

Mentioned are chloroform, dichloromethane, tetrachloroethane, and mono or dichlorobenzene.

### (Ketones)

Mentioned is methyl isobutyl ketone.

One alone or two or more kinds of these organic solvents can be used either singly or as a mixed solvent thereof.

In particular, the organic solvent for use in the present invention is more preferably n-hexane, n-heptane, n-octane, benzene or xylene.

### <Additive>

In the present invention, for the purpose of more stabilizing the emulsion, an additive may be added to the aqueous phase within a range not detracting from the advantageous effects of the present invention. Such an additive includes a water-soluble salt such as sodium carbonate, calcium carbonate, potassium carbonate, sodium phosphate, potassium phosphate, calcium phosphate, sodium chloride or potassium chloride. One alone or two or more kinds of these additives can be used either singly or as combined.

### <Catalyst>

### (Urethanation Catalyst)

In the present invention, for the urethanation catalyst to be used in the case of synthesizing an urethane prepolymer of the component (B12) or in the case where the hollow microballoons are formed of a urethane(urea)resin, any appropriate one can be used with no limitation. Specific examples are mentioned: Triethylenediamine, hexamethylenetetramine, N,N-dimethyloctylamine, N,N,N′,N′-tetramethyl-1,6-diaminohexane, 4,4′-trimethylenebis(1-methylpiperidine), 1,8-diazabicyclo-(5,4,0)-7-undecene, dimethyltin dichlcoride, dimethyltin bis(isooctylthio glycolate), dibutyltin dichloride, dibutyltin dilaurate, dibutyltin maleate, dibutyltin maleate polymer, dibutyltin diricinolate, dibutyltin bis(dodecyl mercaptide), dibutyltin bis(isooctylthio glycolate), dioctyltin dichloride, dioctyltin maleate, dioctyltin maleate polymer, dioctyltin bis(butyl maleate), dioctyltin dilaurate, dioctyltin diricinolate, dioctyltin dioleate, dioctyltin di(6-hydroxy)caproate, dioctyltin bis(isooctylthio glycolate), didodecyltin diricinolate, various metal salts such as copper oleate, copper acetylacetonate, iron acetylacetonate, iron naphthenate, iron lactate, iron citrate, iron gluconate, potassium octanoate, and 2-ethylhexyl titanate.

### (Amidation Catalyst)

For the amidation catalyst to be used in the case where the hollow microballoons are formed of an amide resin, any appropriate one can be used with no limitation. Specific examples include boron and sodium dihydrogen phosphate.

### <Particle Size of Hollow Microballoons>

The average particle size of the hollow microballoons of the present invention is not specifically limited, but is preferably 1 μm to 500 μm, more preferably 5 μm to 200 μm, most preferably 10 to 100 μm. Within the range, the hollow microballoons can express excellent polishing characteristics when used in CMP polishing pads.

For measurement of the average particle size of the hollow microballoons, a known method is employable. Specifically an image analysis method is employable. Using an image analysis method, the particle size can be measured easily. The average particle size is an average particle size of primary particles. For measurement of the average particle size according to an image analysis method, for example, a scanning electron microscope (SEM) can be used.

### <Bulk Density of Hollow Microballoons>

The bulk density of the hollow microballoons of the present invention is, though not specifically limited, preferably 0.01 to 0.5 g/cm³, more preferably 0.02 to 0.3 g/cm³. Within the range, optimum fine pores can be formed on the polishing surface of CMP polishing pads.

### <Ash Content in Hollow Microballoons>

The ash content in the hollow microballoons of the present invention is, though not specifically limited, preferably 0.5 parts by mass or less per 100 parts by mass of the hollow microballoons, as measured according to the method described in the section of Examples to be given below, more preferably 0.3 parts by mass or less, even more preferably 0.1 parts by mass or less, and is most preferably unmeasurable. Within in the range, when the microballoons are used in CMP polishing pads, defects of wafers can be reduced.

### <Application to CMP Polishing Pad>

The CMP polishing pad of the present invention contains the above-mentioned hollow microballoons. Containing the microballoons, the CMP polishing pad can express excellent durability and excellent polishing characteristics.

As a method for producing such a CMP polishing pad, a known method is employable with no limitation. A resin, for example, a urethane resin containing the hollow microballoons of the present invention is cut and surface-polished to give a CMP polishing pad having fine pores on the polishing surface of the urethane resin.

In the case of the CMP polishing pad formed of a urethane resin, the urethane resin to be used can be produced in any known method with no limitation. For example, in one method usable here, an isocyanate group-having compound, an active hydrogen group-having compound having an active hydrogen polymerizable with an isocyanate group, and the hollow microballoons of the present invention are uniformly mixed and dispersed and then cured.

The curing method is not also specifically limited, and any known method is employable. Specifically a dry method such as a one-pot method or a prepolymer method, and a wet method using a solvent can be used. Above all, a dry method is preferably employed.

In the case of the CMP polishing pad formed of a urethane resin, the amount of the hollow microballoons of the present invention to be blended in the urethane resin is preferably 0.1 to 20 parts by mass relative to 100 parts by mass of the total of the isocyanate group-having compound and the active hydrogen group-having compound having an active hydrogen polymerizable with an isocyanate, more preferably 0.2 to 10 parts by mass, even more preferably 0.5 to 8 parts by mass. Within the range, excellent polishing characteristics can be expressed.

In the present invention, it is more favorable that, the polyrotaxane monomer (A) in the present invention is contained as the active hydrogen group-having compound having an active hydrogen polymerizable with an isocyanate, for more improving polishing characteristics.

In the present invention, the pattern of the CMP polishing pad is not specifically limited. For example, the surface may have a grooved structure. The grooved structure of the CMP polishing pad is preferably a form capable of retaining and renewing slurry and specifically includes X (stripe) grooves, XY lattice grooves, concentric grooves, through-holes, non-through holes, polygonal prisms, columns, spiral grooves, eccentric grooves, radical grooves, and a combination of these grooves.

The method for forming the grooved structure of the CMP polishing pad is not specifically limited. For example, there are mentioned a production method of casting the above-mentioned compounds into a mold having a predetermined grooved structure and curing it therein, and a production method of forming a grooved structure using a prepared resin, for example, a mechanically cutting method using a tool having bite of a predetermined size, a pressing method of pressing a resin with a pressing plate having a predetermined surface profile, a production method by photolithography, a production method using a printing method, and a production method with a laser light such as a carbon dioxide laser.

### EXAMPLES

Next, the present invention is described in detail with reference to Examples and Comparative Examples, but the present invention is not limited to these Examples. In the following Examples and Comparative Examples, the constituent components and evaluation methods are as mentioned below.

### (Molecular Weight Measurement: Gel Permeation Chromatography (GPC Measurement))

For GPC measurement, a liquid chromatogram apparatus (by Nihon Waters K.K.) was sued. For the column, Shodex GPC KF-802 (exclusion limit molecular weight: 5,000), KF802.5 (exclusion limit molecular weight: 20,000), KF-803 (exclusion limit molecular weight: 70,000), KF-804 (exclusion limit molecular weight: 400,000), and KF-805 (exclusion limit molecular weight: 2,000,000), all by by Showa Denko K.K. were appropriately used depending on the molecular weight of the sample to be analyzed. As a developing liquid, dimethylformamide was used, and the sample was analyzed at a flow rate of 1 ml/min and a temperature of 40° C. Polystyrene was used as a standard sample, and the weight-average molecular weight was determined by comparative conversion. As a detector, a differential diffractometer was used.

### (Ash Content)

The hollow microballoons were fired at a temperature of 600° C., and the ash content is a proportion of the mass of the firing residue and the mass of the hollow microballoons before firing.

### <Constituent Components>

### (A) Polyrotaxane Monomer

RX-1: Polyrotaxane monomer having a hydroxy group in the side chain, having a number-average molecular weight of the side chain of about 350, and having a weight-average molecular weight of 165,000.
RX-2: Polyrotaxane monomer having an amino group in the side chain, having a number-average molecular weight of the side chain of about 400, and having a weight-average molecular weight of 78,000.

### (Production Method for Polyrotaxane Monomer (A))

### (1-1) Preparation of PEG-COOH:

As a polymer for an axial molecule, a linear polyethylene glycol (PEG) having a molecular weight of 10,000 was prepared. PEG: 10 g, TEMPO (2,2,6,6-tetramethyl-1-piperidinyloxy radical): 100 mg, and sodium bromide: 1 g were dissolved in 100 mL of water. 5 mL of an aqueous sodium hypochlorite solution (effective chlorine concentration 5%) was added to the solution, and stirred at room temperature for 10 minutes. Subsequently 5 mL of ethanol was added to terminate the reaction. This was extracted with 50 mL of methylene chloride, then methylene chloride was evaporated away, and the residue was dissolved in 250 mL of ethanol for reprecipitation for 12 hours at a temperature of −4° C. to give PEG-COOH, which was then collected and dried.

### (1-2) Preparation of Polyrotaxane:

3 g of PEG-COOH prepared in the above and 12 g of α-cyclodextrin (α-CD) were separately dissolved in 50 mL of water at 70° C., and the resultant solutions were mixed by fully shaking them. Next, the resultant mixed solution was reprecipitated at a temperature of 4° C. for 12 hours, and the precipitated encapsulation complex was lyophilized and collected. Subsequently 0.13 g of adamantane amine was dissolved in 50 ml of dimethylformamide (DMF) at room temperature, and then the above encapsulation complex was added thereto and rapidly mixed by fully shaking them. Subsequently 0.38 g of a reagent benzotriazol-1-yl-oxy-tris(dimethylamino)phosphonium hexafluorophosphate was dissolved in 5 mL of DMF and the resultant solution was added to the above, and mixed by fully shaking them. Further, 0.14 ml of diiospropylethylamine was dissolved in 5 mL of DMF, and the resultant solution was added thereto and mixed by fully shaking them to prepare a slurry reagent.

The slurry reagent prepared in the above was statically kept at 4° C. for 12 hours. Subsequently 50 ml of a mixed solvent DMF/methanol (volume ratio 1/1) was added, mixed and centrifuged to remove the supernatant. Further, this was washed with the above mixed solvent DMF/methanol, washed with methanol, and centrifuged to give a precipitate. The resultant precipitate was dried in vacuum and dissolved in 50 mL of dimethyl sulfoxide (DMSO), and the resultant transparent solution was dropwise added to 700 mL of water to precipitate polyrotaxane. The precipitated polyrotaxane was collected by centrifugal separation, and dried in vacuum. Further, this was dissolved in DMSO, precipitated in water, collected and dried to give a pure polyrotaxane. At that time, the encapsulation number of α-CD was 0.25.

Here, for the encapsulation number, polyrotaxane was dissolved in DMSO-d₆ and analyzed with a ¹H-NMR measurement device (JNM-LA500, by JEOL Corporation), and the encapsulation number was calculated according to the following method.

Here, X, Y and X/(Y−X) have the following means.

X: Integrated value of 4 to 6 ppm cyclodextrin hydroxy group-derived protons

Y: Integrated value of 3 to 4 ppm cyclodextrin and PEG methylene chain-derived protons

X/(Y−X): Proton ratio of cyclodextrin to PEG

First, X/(Y−X) at a maximum encapsulation number of 1 is theoretically precalculated, and the value is compared with X/(Y−X) calculated from the analytical values of the actual compound to calculate the encapsulation number.

(1-3) Introduction of Side Chains into Polyrotaxane:

500 mg of the polyrotaxane purified in the above was dissolved in 50 mL of an aqueous 1 mol/L NaOH solution, 3.83 g (66 mmol) of propylene oxide was added thereto and, in an argon atmosphere, stirred at room temperature for 12 hours. Next, using an aqueous 1 mol/L HCl solution, the above polyrotaxane solution was neutralized to have pH of 7 to 8, dialyzed through a dialysis tube, and lyophilized to give a hydroxypropylated polyrotaxane. The resultant hydroxypropylated polyrotaxane was identified through ¹H-NMR and GPC, and was confirmed to be a hydroxypropylated polyrotaxane having a desired structure.

The modification degree on the hydroxy group of the cyclic molecule by the hydroxypropyl group was 0.5, and the weight-average molecular weight was Mw: 50,000 by GPC measurement.

5 g of the resultant hydroxypropylated polyrotaxane was dissolved in 15 g of ε-caprolactone at 80° C. to prepare a mixed liquid. The mixed liquid was stirred at 110° C. for 1 hour while dry nitrogen was kept blown thereinto, and then 0.16 g of a 50 wt % xylene solution of tin(II) 2-ethylhexanoate was added, and stirred at 130° C. for 6 hours. Subsequently xylene was added to give a solution of side chains-introduced ε-caprolactone-modified polyrotaxane xylene having a nonvolatile concentration of about 35% by mass.

### (1-4) Preparation of Terminal Hydroxy Group-Introduced Side Chain-Modified Polyrotaxane (RX-1):

The ε-caprolactone-modified polyrotaxane xylene solution prepared in the above was dropwise added into xylene, collected and dried to give ε-caprolactone-modified polyrotaxane (RX-1).

The physical properties of the polyrotaxane monomer (A): RX-1 were as follows.

Polyrotaxane weight-average molecular weight Mw (GPC): 165,000

Side chain modification degree: 0.5 (50% as displayed in %)

Side chain molecular weight: number-average molecular weight about 350

This is a polyrotaxane monomer (A) having a hydroxy group as a polymerizable group at the terminal of the side chain.

### (1-5) Preparation of Amino Group-Introduced Polyrotaxane:

5 g of the polyrotaxane prepared in the above (1-2) was dispersed in 100 mL of pyridine, and cooled in an ice bath. Subsequently, 14.3 g of paratoluenesulfonyl chloride was added and reacted at 5° C. for 6 hours. Subsequently the reaction liquid was poured into 1000 mL of deionized water to precipitate a solid, and the solid was collected on a glass filter.

The resultant solid was washed with a large amount of deionized water and diethyl ether, and dried in vacuum to give a tosylated polyrotaxane. The tosylated polyrotaxane was identified and confirmed by ¹H-NMR and GPC. The modification degree with the tosyl group on the hydroxy group of the cyclic molecule was 0.06.

5 g of the synthesized tosylated polyrotaxane was dissolved in 150 mL of dimethylformamide. The solution was dropwise added to a mixed solution of 200 mL of ethylenediamine and 100 mL of dimethylformamide heated at 70° C. in advance, and after the dropwise addition, these were reacted for 5 hours at 70° C. Subsequently the reaction liquid was poured into 3 L of diethyl ether to precipitate a solid, and the precipitated solid was collected by centrifugal separation. Subsequently the solid was dissolved in DMF, and reprecipitated in diethyl ether for purification, and then the resultant solid was dried to give an amino group-introduced polyrotaxane.

### (1-6) Preparation of Terminal Amino Group-Introduced Side Chain-Modified Polyrotaxane (RX-2):

3.6 g of ε-caprolactam was heated and melted at 150° C. in a nitrogen flow, and 5.0 g of the above-mentioned amino group-introduced polyrotaxane and a solution of 0.3 g of tin octylate dissolved in 2.0 g of toluene were added thereto. Subsequently this was heated up to 190° C., and reacted at 190° C. for 1 hour. The resultant reaction product was dropwise added to 200 mL of methanol, collected and dried to give a terminal amino group side chain introduced modified polyrotaxane (RX-2).

The physical properties of the polyrotaxane monomer (A): RX-2 were as follows.

Polyrotaxane weight-average molecular weight Mw (GPC): 78,000

Side chain modification degree: 0.06 (50% as displayed in %)

Side chain molecular weight: number-average molecular weight about 400

This is a polyrotaxane monomer (A) having an amino group as a polymerizable group at the terminal of the side chain.

(B) polymerizable monomer other than the (A) polyrotaxane monomer having at least two polymerizable functional groups in the molecule
(B1) Component: Polyfunctional isocyanate compound having at least two isocyanate groups
(B12) Component: Urethane prepolymer
Pre-1: Terminal isocyanate urethane prepolymer having an iso(thio)cyanate equivalent of 905

### (Production Method for Pre-1)

In a flask equipped with a nitrogen-introducing tube, a thermometer and a stirrer, 50 g of 2,4-tolylene diisocyanate, 90 g of polyoxytetramethylene glycol (number-average molecular weight: 1,000) and 12 g of diethylene glycol were reacted in a nitrogen atmosphere at 80° C. for 6 hours to give a terminal isocyanate urethane prepolymer (Pre-1) having an isocyanate equivalent of 905.

(B3) Component: Polyfunctional amine compound
EDA: ethylenediamine
(B5) Component: melamine formaldehyde prepolymer compound

### Nikaresin S-260 (by Nippon Carbide Industries Co., Inc.)

(Organic solvent)

### Tol: Toluene

### (Emulsifier)

PVA: Polyvinyl alcohol of a completely saponified type having an average polymerization degree of about 500
ET/AMA: Polyethylene-anhydrous maleic acid (average molecular weight 100,000 to 500,000)

### Example 1

0.11 parts by mass of the component (A) RX-1 and 1 part by mass of the component (B) Pre-1 were dissolved in 15 parts by mass of toluene to prepare a component (a). Next, 10 parts by mass of PVA was dissolved in 150 parts by mass of water to prepare a component (b). Next, the prepared component (a) and component (b) were mixed, and stirred under the condition of 2,000 rpm×10 minutes at 25° C. using a high-speed shear disperser to give an O/W emulsion. At 25° C., an aqueous solution of 0.04 parts by mass of ethylene diamine dissolved in 30 parts by mass of water was dropwise added to the prepared O/W emulsion. After the dropwise addition, this was slowly stirred at 25° C. for 60 minutes, and then stirred at 60° C. for 4 hours to give a dispersion of microballoons of a urethane(urea) resin. The microballoons were taken out of the resultant microballoon dispersion by filtration, dried in vacuum at a temperature of 60° C. for 24 hours, and then classified with a classifier to collect hollow microballoons 1. In filtrating the microballoon dispersion, ethylenediamine was not detected in the filtrate.

The component (A) was 9.6 parts by mass relative to 100 parts by mass of the total of the component (A) and the component (B) in the obtained hollow microballoons 1.

The average particle size of the hollow microballoons 1 was about 25 μm, the bulk density thereof was 0.1 g/cm³, and no ash was detected.

### Example 2

Hollow microballoons 2 were produced according to the same method as in Example 1, except that the component (A) RX-1 was changed to 1.05 parts by mass and ethylenediamine was changed to 0.01 parts by mass.

The proportion of the component (A) was 51 parts by mass relative to 100 parts by mass of the total of the component (A) and the component (B) in the obtained hollow microballoons 2.

The average particle size of the hollow microballoons 2 was about 30 μm, the bulk density thereof was 0.3 g/cm³, and no ash was detected.

### Example 3

Hollow microballoons 3 were produced according to the same method as in Example 1, except that the component (A) RX-1 was changed to 0.01 parts by mass and ethylenediamine was changed to 0.05 parts by mass.

The proportion of the component (A) was 0.9 parts by mass relative to 100 parts by mass of the total of the component (A) and the component (B) in the obtained hollow microballoons 3.

The average particle size of the hollow microballoons 3 was about 25 μm, the bulk density thereof was 0.1 g/cm³, and no ash was detected.

### Comparative Example 1

Hollow microballoons 4 were produced according to the same method as in Example 1, except that the component (A) was not used and ethylenediamine was changed to 0.05 parts by mass.

The proportion of the component (A) was 0 part by mass relative to 100 parts by mass of the total of the component (A) and the component (B) in the obtained hollow microballoons 4.

The average particle size of the hollow microballoons 4 was about 25 μm, the bulk density thereof was 0.1 g/cm³, and no ash was detected.

### Example 4

0.9 parts by mass of the component (A) RX-2 was dissolved in 100 parts by mass of toluene to prepare a component (c). Next, 10 parts by mass of polyethylene-maleic anhydride was mixed in 200 parts by mass of water, and the mixed liquid was controlled to have a pH of 4 with an aqueous 10% sodium hydroxide solution to prepare a component (d). Next, the prepared component (c) and component (d) were mixed, and stirred under the condition of 2,000 rpm×10 minutes at 25° C. using a high-speed shear disperser to give an O/W emulsion. 9 parts by mass of the component (B5) Nikaresin S-260 was added to the prepared O/W emulsion, and stirred at 65° C. for 24 hours, then cooled to 30° C., and was controlled to have a pH of 7.5 with an aqueous ammonia added thereto to give a dispersion of microballoons of a melamine resin. The microballoons were taken out of the resultant microballoon dispersion by filtration, dried in vacuum at a temperature of 60° C. for 24 hours, and then classified with a classifier to collect hollow microballoons 5. In filtrating the microballoon dispersion, melamine was not detected in the filtrate.

The proportion of the component (A) was 9.1 parts by mass relative to 100 parts by mass of the total of the component (A) and the component (B) in the obtained hollow microballoons 5.

The average particle size of the hollow microballoons 5 was about 30 μm, the bulk density thereof was 0.13 g/cm³, and no ash was detected.

### Comparative Example 2

Hollow microballoons 6 were produced according to the same method as in Example 4, except that the component (c) was prepared using 100 parts by mass of toluene alone but not using the component (A). In filtrating the microballoon dispersion, melamine was not detected in the filtrate.

The proportion of the component (A) was 0 part by mass relative to 100 parts by mass of the total of the component (A) and the component (B) in the obtained hollow microballoons 6.

The average particle size of the hollow microballoons 6 was about 30 μm, the bulk density thereof was 0.13 g/cm³, and no ash was detected.

### Example 5

(Production method for CMP polishing pad using hollow microballoons) 24 parts by mass of RX-1 produced in the above and 5 parts by mass of 4,4′-methylenebis(o-chloroaniline) (MOCA) were mixed at 120° C. to give a uniform solution, and then fully degassed to prepare a liquid A. Separately 3.3 parts by mass of the hollow microballoons 1 produced in Example 1 were added to 71 parts by mass of Pre-1 produced in the above and heated up to 70° C., and stirred with a rotation/revolution stirrer to give a uniform solution. The liquid A controlled at 100° C. was added thereto, and stirred with a rotation/revolution stirrer to give a uniform polymerizable composition. The polymerizable composition was cast into a mold, and cured at 100° C. for 15 hours to produce a urethane resin.

The resultant urethane resin was sliced to give CMP polishing urethane resin pads each having a thickness of 1 mm described below.

The polishing rate of the CMP polishing urethane resin pads produced in the above was 4.5 μm/hr, the surface roughness after polishing of wafers that are substances to be polished was 0.14 nm, and the Tabor wear loss in the Tabor wear test carried out for wear resistance evaluation of the CMP polishing pads was 14 mg. The evaluation methods are mentioned below.

(1) Polishing rate: The polishing conditions are shown below. Ten wafer samples were tested.

Under the following conditions, the samples were polished, and the polishing rate was measured. The polishing rate is an average value of the data of the ten wafer samples.

CMP polishing pad: Pad having a size of 500 mmφ and a thickness of 1 mm, with concentric grooves formed on the surface.

Substance to be polished: 2-inch sapphire wafer

Slurry: FUJIMI COMPOL 80, undiluted liquid

Pressure: 4 psi

Rotation number: 45 rpm

Time: 1 hr

(2) Surface roughness (Ra): The surface of each 10 wafer samples polished under the conditions in the above (1) was observed with a nanosearch microscope SFT-4500 (by Shimadzu Corporation) to measure the surface roughness (Ra) thereof. The surface roughness is an average value of the data of the ten wafer samples.
(3) Wear resistance: Using an apparatus of 5130 Model by Tabor Electronics Ltd., a wear loss was measured. The load was 1 kg, the rotation speed was 60 rpm, the rotation number was 1000 rotations, and the wear ring was H-18. In the Tabor wear test, the same portion of the same sample was measured two times in each sample, and the wear resistance was evaluated by the average value of the found data.

### Examples 6 to 9, Comparative Examples 3 to 5

CMP polishing urethane resin pads were produced and evaluated in the same manner as in Example 5 except that the composition shown in Table 1 was used. The results are shown in Table 1.

TABLE 1

| | | | | Polishing | Wafer Surface | Wear |
|---|---|---|---|---|---|---|
| | Hollow Microballoons | Urethane Resin Composition | Density | Rate | Roughness | Resistance |
| | (part by mass) | (part by mass) | g/cm³ | μm/hr | Ra nm | mg |
| Example 5 | Microballoons 1 (3.3) | RX-1(24)/Pre-1(7 l)/MOCA(5) | 0.80 | 4.5 | 0.14 | 14 |
| Example 6 | Microballoons 2 (3.3) | RX-1(24)/Pre-1(7 l)/MOCA(5) | 0.95 | 4.2 | 0.16 | 17 |
| Example 7 | Microballoons 3 (3.3) | RX-1(24)/Pre-1(7 l)/MOCA(5) | 0.80 | 4.1 | 0.21 | 18 |
| Comparative | Microballoons 4 (3.3) | RX-1(24)/Pre-1(7 l)/MOCA(5) | 0.80 | 3.9 | 0.22 | 21 |
| Example 3 | | | | | | |
| Example 8 | Microballoons 5 (3.3) | RX-1(24)/Pre-1(7 l)/MOCA(5) | 0.85 | 4.2 | 0.17 | 18 |
| Comparative | Microballoons 6 (3.3) | RX-1(24)/Pre-1(7 l)/MOCA(5) | 0.85 | 3.5 | 0.23 | 25 |
| Example 4 | | | | | | |
| Example 9 | Microballoons 1 (3.3) | Pre-1(88)/MOCA(12) | 0.80 | 3.0 | 0.20 | 55 |
| Comparative | Microballoons 4 (3.3) | Pre-1(88)/MOCA(12) | 0.80 | 2.0 | 0.25 | 70 |
| Example 5 | | | | | | |

As known from the results in Table 1, the CMP polishing pads using the hollow microballoons containing the polyrotaxane monomer (A) obtained according to the production method of the present invention have an excellent polishing rate and improved polishing characteristics capable of more smoothly polishing the substances to be polished, wafers. Further the CMP polishing pads have good results in the wear resistance test, and also have excellent durability.

As described above, it is preferable that the resin composition of the CMP polishing pad base also contains the polyrotaxane monomer (A), but as obvious from comparison between Example 9 and Comparative Example 5, even in the case where the resin composition of the CMP polishing pad base does not contain the component (A), the polishing characteristics can be improved by using the hollow microballoons of the present invention.

1. Hollow microballoons comprising a resin produced by polymerizing a polymerizable composition that contains (A) a polyrotaxane monomer having at least two polymerizable functional groups in a molecule and (B) a polymerizable monomer other than the (A) polyrotaxane monomer having at least two polymerizable functional groups in the molecule.

2. The hollow microballoons according to claim 1, wherein a content of the (A) polyrotaxane monomer having at least two polymerizable functional groups in the molecule in the polymerizable composition is 1 to 50 parts by mass relative to 100 parts by mass of the total of the content of the (A) polyrotaxane monomer having at least two polymerizable functional groups in the molecule and a content of the (B) polymerizable monomer other than the (A) polyrotaxane monomer having at least two polymerizable functional groups in the molecule.

3. The hollow microballoons according to claim 1, wherein the resin comprises at least one selected from the group consisting of a urethane(urea) resin, a melamine resin, a urea resin and an amide resin.

4. The hollow microballoons according to claim 1, wherein a polymerizable functional group of the (A) polyrotaxane monomer having at least two polymerizable functional groups in the molecule is a hydroxy group or an amino group.

5. The hollow microballoons according to claim 1, wherein a cyclic molecule of the (A) polyrotaxane monomer having at least two polymerizable functional groups in the molecule has a side chain.

6. The hollow microballoons according to claim 5, wherein a number-average molecular weight of the side chain of the (A) polyrotaxane monomer having at least two polymerizable functional groups in the molecule is 5,000 or less.

7. The hollow microballoons according to claim 5, wherein the side chain of the (A) polyrotaxane monomer having at least two polymerizable functional groups in the molecule has the at least two polymerizable functional groups.

8. A polishing pad for CMP containing the hollow microballoons of claim 1.
